(19) United States
(12) Patent Application Publication
(10) Pub. No.: US 2025/0267996 A1
(43) Pub. Date: Aug. 21, 2025

(54) DISPLAY DEVICE

(71) Applicant: LG Display Co., Ltd., Seoul (KR)

(72) Inventors: SungJoon MIN, Goyang-si (KR); Yeonjun OH, Incheon (KR); Dojoong KIM, Seoul (KR); JunHyuk SONG, Seoul (KR); Taehyun KIM, Uijeongbu-si (KR)

(73) Assignee: LG Display Co., Ltd., Seoul (KR)

(21) Appl. No.: 18/888,037

(22) Filed: Sep. 17, 2024

(30) Foreign Application Priority Data
Feb. 20, 2024 (KR) 10-2024-0024161

(51) Int. Cl. H01L 33/62; H01L 25/16; H01L 27/12; H04R 1/02

(52) U.S. Cl. CPC H10H 20/857; H01L 25/167; H04R 1/028; H10D 86/411; H10D 86/443; H10D 86/60; H04R 2499/15

(57) ABSTRACT

A display device includes a stretchable lower substrate, a plurality of pixel plate patterns disposed to be spaced apart from each other on the lower substrate and having a plurality of sub pixels, a plurality of speaker plate patterns disposed to be spaced apart from each other on the lower substrate and alternately disposed with the plurality of pixel plate patterns, a plurality of connection lines disposed between the plurality of pixel plate patterns and between the plurality of pixel plate patterns and the plurality of speaker plate patterns, and a sound unit disposed on each of the plurality of speaker plate patterns. Accordingly, the plurality of speaker plate patterns are formed in an area between the plurality of pixel plate patterns so that the sound unit can be embedded in the display device.

### CROSS-REFERENCE TO RELATED APPLICATIONS

This application claims priority to Korean Patent Application No. 10-2024-0024161 filed on Feb. 20, 2024, in the Korean Intellectual Property Office, the entire contents of which is hereby expressly incorporated by reference into the present application.

### BACKGROUND

### Field

The present disclosure relates to a display device, and more particularly to a stretchable display device in which a speaker is embedded.

### Discussion of the Related Art

Among display devices which are used as a monitor of a computer, a television, or a cellular phone, there are an organic light emitting display device (OLED) which is a self-emitting device, a liquid crystal display device (LCD) which requires a separate light source, and the like.

An applicable range of the display device can be diversified into personal digital assistants as well as monitors of computers and televisions. In applications, a display device with a large display area and a reduced volume and weight is needed and is being studied.

Further, a display device is manufactured by forming a display unit, a wiring line, and the like on a flexible substrate made of a flexible material such as plastics so that the display device can be stretchable in a specific direction and changed in various forms. Such display device is getting attention as a next generation display device.

### SUMMARY OF THE DISCLOSURE

An object to be achieved by the present disclosure is to provide a display device in which a speaker is embedded.

Another object to be achieved by the present disclosure is to provide a display device which can output a stereophonic sound.

Still another object to be achieved by the present disclosure is to provide a display device in which an empty space between a plurality of pixel plate patterns is utilized as a speaker area.

Still another object to be achieved by the present disclosure is to provide a display device including an enclosure formed using a lower substrate and an upper substrate.

Still another object to be achieved by the present disclosure is to provide a display device which uses a high potential power line as a speaker driving line.

Still another object to be achieved by the present disclosure is to provide a display device in which some wiring line is detoured to be formed as a speaker area to simplify a structure of a connection line.

Still another object to be achieved by the present disclosure is to provide a display device which can amplify and output a sound of a sound unit.

Another object of the present disclosure is to provide an improved display device which address the limitations and disadvantages associated with the related art.

Objects of the present disclosure are not limited to the above-mentioned objects, and other objects, which are not mentioned above, can be clearly understood by those skilled in the art from the following descriptions.

According to an aspect of the present disclosure, a display device includes a stretchable lower substrate; a plurality of pixel plate patterns disposed to be spaced apart from each other on the lower substrate and having a plurality of sub pixels; a plurality of speaker plate patterns disposed to be spaced apart from each other on the lower substrate and alternately disposed with the plurality of pixel plate patterns; a plurality of connection lines disposed between the plurality of pixel plate patterns and between the plurality of pixel plate patterns and the plurality of speaker plate patterns; and a sound unit disposed on each of the plurality of speaker plate patterns. Accordingly, the plurality of speaker plate patterns are formed in an area between the plurality of pixel plate patterns so that the sound unit can be embedded in the display device.

Other detailed matters of the example embodiments are included in the detailed description and the drawings.

According to one or more aspects of the present disclosure, a speaker is embedded in the display device to output a stereophonic sound.

According to one or more aspects of the present disclosure, in the display device, a speaker can be embedded by utilizing a space between a plurality of pixel plate patterns.

According to one or more aspects of the present disclosure, in the display device, a lower substrate and an upper substrate are partially patterned to effectively amplify and output a sound of the speaker.

According to one or more aspects of the present disclosure, in the display device, the high potential power line is used as a speaker driving line to simplify the structure of the display device.

According to one or more aspects of the present disclosure, in the display device, some wiring line is detoured to be formed as a speaker area to simplify the structure of the connection line.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a plan view of a display device according to an example embodiment of the present disclosure;

FIGS. 2 and 3 are enlarged plan views of an active area of a display device according to an example embodiment of the present disclosure;

FIG. 4 is a cross-sectional view of a pixel area of a display device according to an example embodiment of the present disclosure;

FIGS. 5A and 5B are cross-sectional views of a speaker area of a display device according to an example embodiment of the present disclosure;

FIG. 6 is an enlarged plan view of an active area of a display device according to another example embodiment of the present disclosure;

FIG. 7 is a schematic plan view of a speaker area of a display device according to another example embodiment of the present disclosure;

FIG. 8 is a cross-sectional view of a display device according to another example embodiment of the present disclosure;

FIG. 9 is an enlarged plan view of an active area of a display device according to still another example embodiment of the present disclosure; and

FIG. 10 is a cross-sectional view of a display device according to still another example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “over,” “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated. Further, the term “can” fully encompasses all the meanings and coverages of the term “may.”

The features of various embodiments of the present disclosure can be partially or entirely adhered to or combined with each other and can be interlocked and operated in technically various ways, and the embodiments can be carried out independently of or in association with each other. Hereinafter, various embodiments of the present disclosure will be described in detail with reference to accompanying drawings. All the components of each display device according to all embodiments of the present disclosure are operatively coupled and configured.

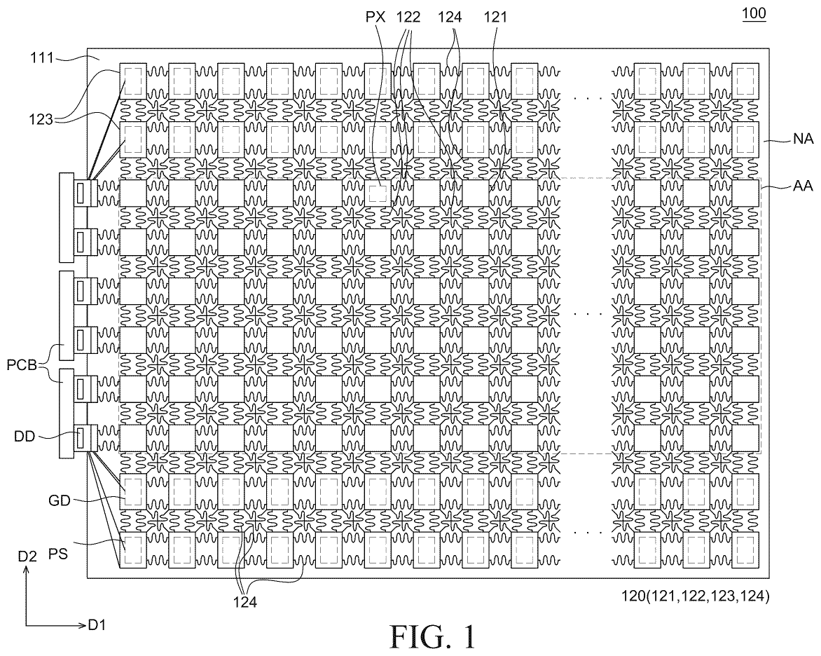

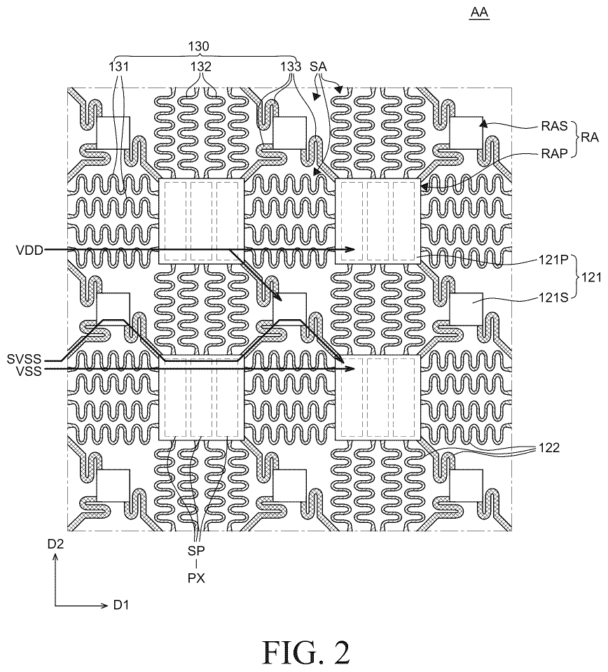

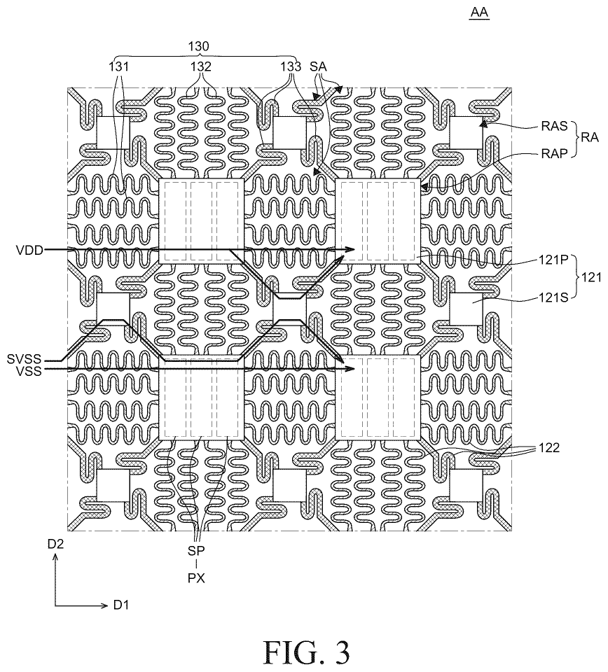

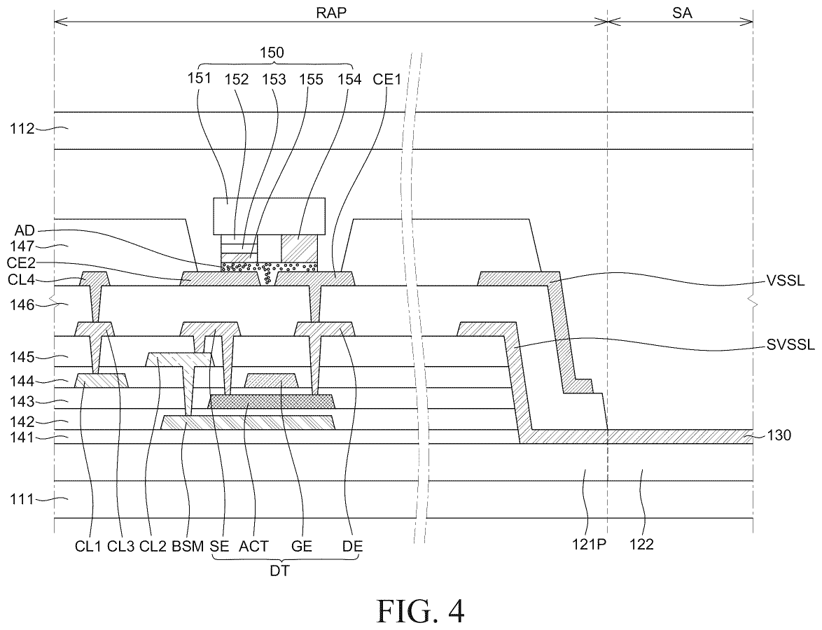

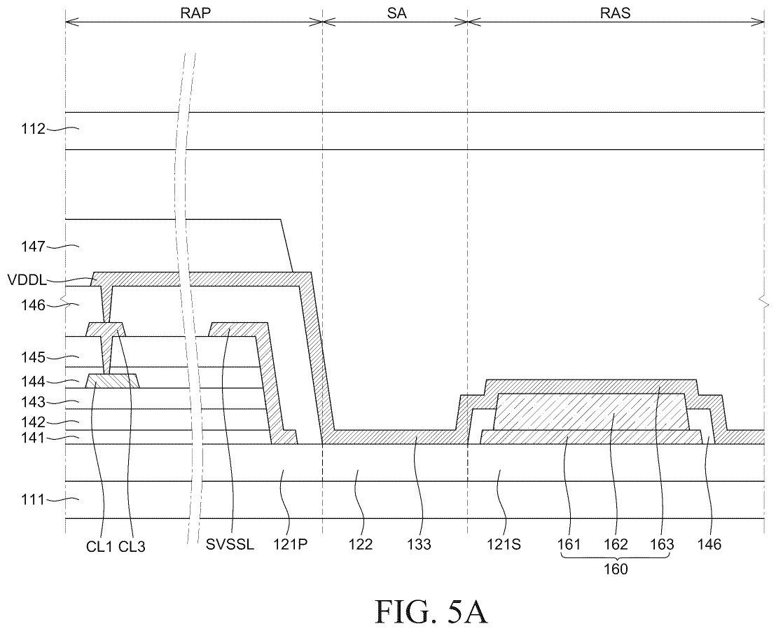

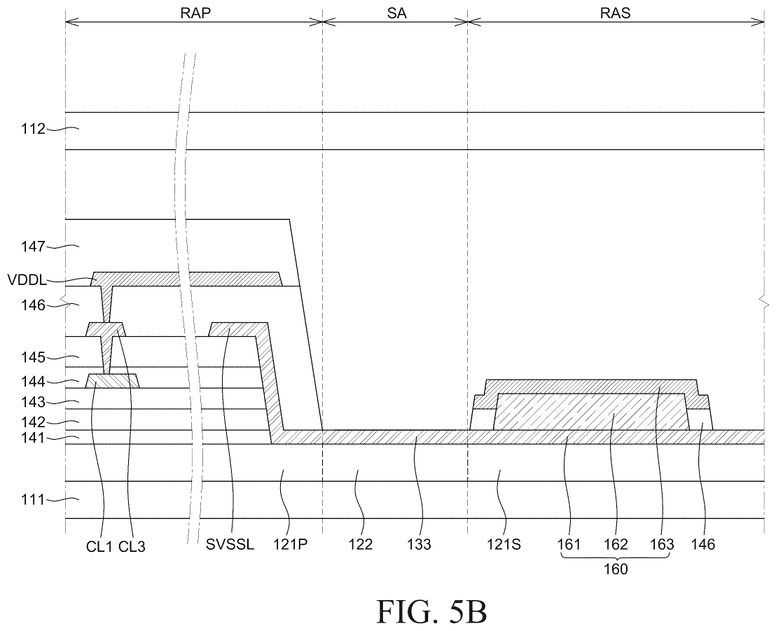

FIG. 1 is a plan view of a display device according to an example embodiment of the present disclosure. FIGS. 2 and 3 are enlarged plan views of an active area of a display device according to an example embodiment of the present disclosure. FIG. 4 is a cross-sectional view of a pixel area of a display device according to an example embodiment of the present disclosure. FIGS. 5A and 5B are cross-sectional views of a speaker area of a display device according to an example embodiment of the present disclosure. Specifically, FIG. 4 is a cross-sectional view for explaining a sub pixel SP and FIGS. 5A and 5B are cross-sectional views for explaining a sound unit 160.

First, a display device 100 according to an example embodiment of the present disclosure is capable of displaying images even in a bent or extended state and can be also referred to as a stretchable display device 100, a flexible display device 100, and an extendable display device 100. As compared with the general display devices of a related art, the display device 100 can have not only a high flexibility, but also stretchability. Therefore, the user can bend or extend a display device 100 and a shape of a display device 100 can be freely changed in accordance with manipulation of a user. For example, when the user pulls the display device 100 by holding ends of the display device, the display device 100 can be extended to the pulling direction of the user. Alternatively, when the user disposes the display device 100 on an outer surface which is not flat, the display device 100 can be disposed to be bent in accordance with the shape of the outer surface. Further, when a force applied by the user is removed, the display device 100 can return to its original shape.

Referring to FIGS. 1 to 5B together, a lower substrate 111 is a substrate which supports and protects several components of the display device 100. The lower substrate 111 can support a pattern layer 120 on which the pixels PX, the gate driver GD, and the power supply PS are formed.

An upper substrate 112 is a substrate which covers and protects several components of the display device 100. The upper substrate 112 can cover the pixels PX, the gate driver GD, and the power supply PS.

The lower substrate 111 and the upper substrate 112 which are flexible substrates can be configured by an insulating material which is bendable or extendable. The lower substrate 111 and the upper substrate 112 are formed of a film having flexibility. For example, the lower substrate 111 and the upper substrate 112 can be formed of a silicon rubber such as polydimethylsiloxane (PDMS) or an elastomer such as polyurethane (PU) and polytetrafluoroethylene (PTFE) and thus have a flexibility. Further, the materials of the lower substrate 111 and the upper substrate 112 can be the same, but are not limited thereto and can vary.

The lower substrate 111 and the upper substrate 112 are flexible substrates so as to be reversibly expandable and contractible. Accordingly, the lower substrate 111 can be referred to as a lower stretchable substrate, a lower stretching substrate, a lower extending substrate, a lower ductile substrate, a lower flexible substrate, a first stretchable substrate, a first stretching substrate, a first extending substrate, a first ductile substrate, a first flexible substrate, or the like. The upper substrate 112 can be referred to as an upper stretchable substrate, an upper stretching substrate, an upper extending substrate, an upper ductile substrate, an upper flexible substrate, a second stretchable substrate, a second stretching substrate, a second extending substrate, a second ductile substrate, a second flexible substrate, or the like.

Moduli of elasticity of the lower substrate 111 and the upper substrate 112 can be several MPa to several hundreds of MPa. Further, a ductile breaking rate of the lower substrate 111 and the upper substrate 112 can be 100% or higher. Here, the ductile breaking rate refers to a stretching rate at a timing when an object to be stretched is broken or cracked. A thickness of the lower substrate 111 can be 10 μm to 1 mm, but is not limited thereto.

The lower substrate 111 includes an active area AA and a non-active area NA enclosing the active area AA. However, the active area AA and the non-active area NA are not mentioned to be limited to the lower substrate 111, but mentioned for the entire display device 100.

The active area AA is an area in which images are displayed in the display device 100 and a plurality of pixels PX is disposed in the active area AA. Further, each pixel PX can include a display element and various driving elements for driving the display element. Various driving elements can refer to at least one thin film transistor (TFT) and a capacitor, but are not limited thereto. The plurality of pixels PX can be connected to various wiring lines to be driven, respectively. For example, each of the plurality of pixels PX can be connected to various wiring lines, such as a scan line, a data line, a high potential voltage line, a low potential voltage line, a reference voltage line, and an initialization voltage line.

The non-active area NA is an area where no image is displayed. The non-active area NA can be an area adjacent to the active area AA. Further, the non-active area NA can be adjacent to the active area AA to enclose the active area AA. For instance, the non-active area NA can surround the active area AA entirely or only in parts. However, it is not limited thereto so that the non-active area NA corresponds to an area excluding the active area AA from the lower substrate 111 and can be modified and separated in various forms. In the non-active area NA, components for driving a plurality of pixels PX disposed in the active area AA, such as a gate driver GD and a power supply PS, can be disposed. Further, in the non-active area NA, a plurality of pads connected to the data driver DD and the printed circuit board PCB can be disposed and each pad can be connected to each of the plurality of pixels PX of the active area AA.

Further, the lower substrate 111 can also be defined to include a plurality of rigid areas RA and malleable areas SA. The plurality of rigid areas RA can be disposed to be spaced apart from each other. The plurality of rigid areas RA can be areas of the lower substrate 111 overlapping the plurality of first plate patterns 121 and the plurality of second plate patterns 123. The plurality of rigid areas RA can be areas in which the plurality of first plate patterns 121 and the plurality of second plate patterns 123 are disposed to have a rigidity.

The malleable area SA can be an area which encloses each of the plurality of rigid areas RA. The malleable area SA can be an area which does not overlap the plurality of first plate patterns 121 and the plurality of second plate patterns 123. The malleable area SA is an area between the plurality of first plate patterns 121 and the plurality of second plate patterns 123. The malleable area SA can include an area in which the plurality of first line patterns 122 and the plurality of second line patterns 124 are disposed. Further, the malleable area SA can include an area in which the pattern layer 120 is not disposed. The malleable area SA can be an area in which the plurality of first plate patterns 121 and the plurality of second plate patterns 123 are not disposed to be flexibly deformable.

Accordingly, in the plurality of rigid areas RA, the plurality of first plate patterns 121 and the plurality of second plate patterns 123 are disposed. In the malleable area SA, the plurality of first plate patterns 121 and the plurality of second plate patterns 123 are not disposed. Therefore, the plurality of rigid areas RA can be more rigid than the malleable area SA. At this time, the malleable area SA and the plurality of rigid areas RA are not mentioned to be limited to the lower substrate 111, but can be mentioned for the entire display device 100.

In the meantime, some of the plurality of rigid areas RA can be a plurality of pixel areas RAP and the other rigid areas RA can be a plurality of speaker areas RAS. In the plurality of pixel areas RAP, a pixel plate pattern 121P, among the plurality of first plate patterns 121, is disposed. In the plurality of speaker areas RAS, a speaker plate pattern 121S, among the plurality of first plate patterns 121, is disposed, which will be described in more detail below.

Next, the pattern layer 120 is disposed on the lower substrate 111. The pattern layer 120 includes a plurality of first plate patterns 121 and a plurality of first line patterns 122 disposed in the active area AA and a plurality of second plate patterns 123 and a plurality of second line patterns 124 disposed in the non-active area NA.

A plurality of plate patterns is disposed in the active area AA and the non-active area NA. The plurality of plate patterns includes a plurality of first plate patterns 121 disposed in the active area AA and a plurality of second plate patterns 123 disposed in the non-active area NA. The plurality of first plate patterns 121 and the plurality of second plate patterns 123 can be disposed in the form of separate islands. The plurality of first plate patterns 121 and the plurality of second plate patterns 123 can be individually separated. Therefore, the plurality of first plate patterns 121 and the plurality of second plate patterns 123 can be referred to as first island patterns and second island patterns or first individual patterns and second individual patterns.

A size of each of the plurality of second plate patterns 123 can be larger than a size of each of the plurality of first plate patterns 121. In each of the plurality of second plate patterns 123, one stage of the gate driver GD can be disposed. Therefore, an area occupied by various circuit configurations which configure one stage of the gate driver GD can be relatively larger than an area occupied by one pixel PX so that a size of each of the plurality of second plate patterns 123 can be larger than a size of each of the plurality of first plate patterns 121.

In the meantime, even though it is illustrated in FIG. 1 that the plurality of second plate patterns 123 is disposed in the non-active area NA on both sides of the active area AA in the second direction D2, this is illustrative so that the plurality of second plate patterns 123 can be disposed in an arbitrary area of the non-active area NA. Further, even though it is illustrated that the plurality of first plate patterns 121 and the plurality of second plate patterns 123 have a rectangular shape, it is not limited thereto. The shapes of the plurality of first plate patterns 121 and the plurality of second plate patterns 123 can vary in various forms.

The plurality of first plate patterns 121 is disposed in the active area AA of the lower substrate 111. The plurality of first plate patterns 121 includes a plurality of pixel plate patterns 121P and a plurality of speaker plate patterns 121S. A plurality of sub pixels SP is formed on the plurality of pixel plate patterns 121P and a sound unit 160 is formed on the plurality of speaker plate patterns 121S.

Referring to FIGS. 2 and 3, in the pixel area RAP, among the plurality of rigid areas RA, the pixel plate pattern 121P is disposed. In the speaker area RAS, the speaker plate pattern 121S is disposed. The plurality of pixel plate patterns 121P is disposed to be spaced apart from each other and the plurality of speaker plate patterns 121S can be also disposed to be spaced apart from each other. Further, the plurality of pixel plate patterns 121P and the plurality of speaker plate patterns 121S can be disposed to be spaced apart from each other.

The plurality of pixel plate patterns 121P can be disposed in a matrix while forming a plurality of rows and a plurality of columns. The plurality of speaker plate patterns 121S can be disposed in a matrix while forming a plurality of rows and a plurality of columns. For example, the plurality of pixel plate patterns 121P can be disposed to be spaced apart from each other with a predetermined interval in the first direction D1. The plurality of pixel plate patterns 121P can be disposed to be spaced apart from each other with a predetermined interval in the second direction D2. For example, the plurality of speaker plate patterns 121S can be disposed to be spaced apart from each other with a predetermined interval in the first direction D1 and the second direction D2.

The plurality of pixel plate patterns 121P and the plurality of speaker plate patterns 121S can be alternately disposed with each other. The plurality of pixel plate patterns 121P and the plurality of speaker plate patterns 121S can be disposed in different rows and different columns. The plurality of speaker plate patterns 121S can be disposed in a direction other than the first direction D1 and the second direction D2 of the plurality of pixel plate patterns 121P, for example, in a diagonal direction of the plurality of pixel plate patterns 121P.

The plurality of sub pixels SP which forms one pixel PX is disposed in one pixel plate pattern 121P. Therefore, a rigid area RA in which the pixel plate pattern 121P is disposed can be also defined as a pixel area RAP. Further, as the sound unit 160 is disposed on one speaker plate pattern 121S, the rigid area RA in which the speaker plate pattern 121S is disposed can be also defined as a speaker area RAS.

A size of one pixel plate pattern 121P can be larger than a size of the speaker plate pattern 121S. An area of the pixel plate pattern 121P can be larger than an area of the speaker plate pattern 121S. Configurations included in the plurality of sub pixels SP, for example, a pixel circuit and a light emitting diode 150, are disposed on the pixel plate pattern 121P so that the pixel plate pattern 121P can be larger than the speaker plate pattern 121S in which only one sound unit 160 is disposed.

Next, the plurality of second plate patterns 123 is disposed in the non-active area NA of the lower substrate 111. The gate driver GD and the power supply PS are formed on the plurality of second plate patterns 123.

The gate driver GD can be mounted on the plurality of second plate patterns 123. The gate driver GD can be formed on the plurality of second plate patterns 123 in a gate in panel (GIP) manner when various elements on the plurality of first plate patterns 121 are manufactured. Therefore, various circuit configurations which configure the gate driver GD, such as transistors, capacitors, and wiring lines, can be disposed on the plurality of second plate patterns 123. One stage which is a circuit which configures the gate driver GD and includes transistors and capacitors can be disposed above each of the plurality of second plate patterns 123. However, the gate driver GD can be mounted in a chip on film (COF) manner, but is not limited thereto.

A power supply PS is disposed on the plurality of second plate patterns 123. The power supply PS can be formed on the second plate pattern 123 adjacent to the gate driver GD. The power supply PS is a plurality of power blocks patterned when various components on the first plate pattern 121 is manufactured and can be formed on the second plate pattern 123. The power supply PS is electrically connected to the gate driver GD of the non-active area NA and the plurality of pixels PX of the active area AA to supply a driving voltage. Specifically, the power supply PS can be electrically connected to the gate driver GD formed on the second plate pattern 123 and the plurality of pixels PX formed on the first plate pattern 121 by means of the second line pattern 124 and the first line pattern 122. For example, the power supply PS can supply a gate driving voltage and a clock signal to the gate driver GD. Further, the power supply PS can supply the power voltage to each of the plurality of pixels PX.

Next, the printed circuit board PCB is connected to an edge of the lower substrate 111. The printed circuit board PCB is a component which transmits signals and voltages for driving the display element from the control unit to the display element. Therefore, the printed circuit board PCB can also be referred to as a driving substrate. A controller, such as an IC chip or a circuit unit, can be mounted on the printed circuit board PCB. Further, on the printed circuit board PCB, a memory, a processor, or the like can also be mounted. The printed circuit board PCB provided in the display device 100 can include a stretching area and a non-stretching area to ensure stretchability. Further, in the non-stretching area, an IC chip, a circuit unit, a memory, a processor, and the like can be mounted. In the stretching area, wiring lines which are electrically connected to the IC chip, the circuit unit, the memory, and the processor can be disposed.

The data driver DD is a component which supplies a data voltage to the plurality of pixels PX disposed in the active area AA. The data driver DD is configured as an IC chip so that it can be also referred to as a data integrated circuit D-IC. Further, the data driver DD can be mounted in the non-stretching area of the printed circuit board PCB. For example, the data driver DD can be mounted on the printed circuit board PCB in the form of a chip on board (COB). However, even though in FIG. 1, it is illustrated that the data driver DD is mounted in a COB manner, the data driver DD can be mounted in a chip on film (COF), a chip on glass (COG), or a tape carrier package (TCP) manner, but it is not limited thereto.

Further, even though in FIG. 1, it is illustrated that one data driver DD is disposed so as to correspond to each of a plurality of columns formed by the plurality of first plate patterns 121 disposed in the active area AA, it is not limited thereto. For example, one data driver DD can be disposed so as to correspond to a plurality of columns formed by the plurality of first plate patterns 121.

Referring to FIGS. 1 to 3, the plurality of line patterns is disposed in the active area AA and the non-active area NA. The plurality of line patterns includes a plurality of first line patterns 122 and a plurality of second line patterns 124.

The plurality of first line patterns 122 is disposed in the active area AA. The plurality of first line patterns 122 is patterns which connect first plate patterns 121 which are adjacent to each other and can be referred to as internal connection patterns. For example, the plurality of first line patterns 122 can be disposed between the plurality of first plate patterns 121. For example, the plurality of first line patterns 122 can be disposed between the plurality of pixel plate patterns 121P. Further, the plurality of first line patterns 122 can be disposed between the plurality of pixel plate patterns 121P and the speaker plate patterns 121S. The plurality of first line patterns 122 can connect adjacent pixel plate patterns 121P to each other or can connect a pixel plate pattern 121P and a speaker plate pattern 121S which are adjacent to each other. The plurality of first line patterns 122 can be disposed in the active area AA of the lower substrate 111.

The plurality of first line patterns 122 is disposed in an area between the plurality of first plate patterns 121 to connect the plurality of first plate patterns 121. Some of the plurality of first line patterns 122 extends in the first direction D1 or the second direction D2 and can connect the pixel plate patterns 121P which are adjacent to each other in the first direction D1 or the second direction D2. The other of the plurality of first line patterns 122 are disposed in an area between the plurality of pixel plate patterns 121P and the plurality of speaker plate patterns 121S to connect the pixel plate pattern 121P and the speaker plate pattern 121S to each other. The other of the plurality of first line patterns 122 extends in a direction other than the first direction D1 and the second direction D2 and can connect the pixel plate pattern 121P and the speaker plate pattern 121S which are adjacent to each other. For example, the other first line patterns 122 extends in an inclined direction to the first direction D1 and the second direction D2 and can connect the pixel plate pattern 121P and the speaker plate pattern 121S which are adjacent to each other.

Next, the plurality of second line patterns 124 of the pattern layer 120 is disposed in the non-active area NA. The plurality of second line patterns 124 connects the first plate pattern 121 and the second plate pattern 123 which are adjacent to each other or connects a plurality of adjacent second plate patterns 123 and is referred to as external connection patterns. The plurality of second line patterns 124 can be disposed between the first plate pattern 121 and the second plate pattern 123 which are adjacent to each other and between the plurality of second plate patterns 123 which is adjacent to each other. For example, the plurality of second line patterns 124 extends in the first direction D1 or the second direction D2 and can connect the second plate patterns 123 which are adjacent to each other in the first direction D1 or the second direction D2. For example, the plurality of second line patterns 124 extends in the first direction D1 or the second direction D2 and can connect the second plate patterns 123 and the first plate pattern 121 which are adjacent to each other in the first direction D1 or the second direction D2.

The plurality of first line patterns 122 and the plurality of second line patterns 124 have a wavy shape. For example, the plurality of first line patterns 122 and the plurality of second line patterns 124 can have a sinusoidal shape. However, the shape of the plurality of first line patterns 122 and the plurality of second line patterns 124 is not limited thereto. For example, the plurality of first line patterns 122 and the plurality of second line patterns 124 can extend in a zigzag pattern. Further, the plurality of first line patterns 122 and the plurality of second line patterns 124 can have various shapes such as a shape in which a plurality of rhombic substrates is connected at their vertexes to be extended or a shape in which semi-circular and quadrant-shaped substrates are connected to each other. Further, the number and the shape of the plurality of first line patterns 122 and the plurality of second line patterns 124 illustrated in FIG. 1 are illustrative and can be changed in various forms depending on the design.

In the meantime, the plurality of first plate patterns 121, the plurality of first line patterns 122, the plurality of second plate patterns 123, and the plurality of second line patterns 124 are rigid patterns. For example, the plurality of first plate patterns 121, the plurality of first line patterns 122, the plurality of second plate patterns 123, and the plurality of second line patterns 124 can be more rigid than the lower substrate 111 and the upper substrate 112.

The plurality of first plate patterns 121, the plurality of first line patterns 122, the plurality of second plate patterns 123, and the plurality of second line patterns 124 which are rigid substrates can be formed of a plastic material having a lower flexibility than the lower substrate 111 and the upper substrate 112. For example, the plurality of first plate patterns 121, the plurality of first line patterns 122, the plurality of second plate patterns 123, and the plurality of second line patterns 124 can be formed of at least one material of polyimide (PI), polyacrylate, and polyacetate. At this time, when the plurality of first plate patterns 121, the plurality of first line patterns 122, the plurality of second plate patterns 123, and the plurality of second line patterns 124 are formed of the same material, the plurality of first plate patterns 121, the plurality of first line patterns 122, the plurality of second plate patterns 123, and the plurality of second line patterns 124 are integrally formed. However, when the plurality of first plate patterns 121, the plurality of first line patterns 122, the plurality of second plate patterns 123, and the plurality of second line patterns 124 can be formed of different materials, but are not limited thereto.

Moduli of elasticity of the plurality of first plate patterns 121, the plurality of first line patterns 122, the plurality of second plate patterns 123, and the plurality of second line patterns 124 can be higher than a modulus of elasticity of the lower substrate 111. The modulus of elasticity is a parameter representing a rate of deformation against the stress applied to the substrate and the higher the modulus of elasticity, the higher the hardness. Therefore, the plurality of first plate patterns 121, the plurality of first line patterns 122, the plurality of second plate patterns 123, and the plurality of second line patterns 124 can be referred to as a plurality of first rigid patterns, a plurality of second rigid patterns, a plurality of third rigid patterns, and a plurality of fourth rigid patterns, respectively. Moduli of elasticity of the plurality of first plate patterns 121, the plurality of first line patterns 122, the plurality of second plate patterns 123, and the plurality of second line patterns 124 can be 1000 times or higher than the moduli of elasticity of the lower substrate 111 and the upper substrate 112, but it is not limited thereto.

In the meantime, in some example embodiments, the lower substrate 111 can be defined to include a plurality of first lower patterns and a second lower pattern. The plurality of first lower patterns can be an area of the lower substrate 111 overlapping the plurality of first plate patterns 121 and the plurality of second plate patterns 123. The second lower pattern can be a remaining area which does not overlap the plurality of first plate patterns 121 and the plurality of second plate patterns 123.

Further, the upper substrate 112 can be defined to include a plurality of first upper patterns and a second upper pattern. The plurality of first upper patterns can be an area overlapping the plurality of the first plate patterns 121 and the plurality of second plate patterns 123 of the upper substrate 112. However, the second upper pattern can be a remaining area which does not overlap the plurality of the first plate patterns 121 and the plurality of second plate patterns 123.

At this time, moduli of elasticity of the plurality of first lower patterns and the first upper pattern can be higher than moduli of elasticity of the second lower pattern and the second upper pattern. For example, the plurality of first lower patterns and the first upper pattern can be formed of the same material as the plurality of first plate patterns 121 and the plurality of second plate patterns 123. The second lower pattern and the second upper pattern can be formed of a material having a modulus of elasticity lower than those of the plurality of first plate patterns 121 and the plurality of second plate patterns 123.

For example, the first lower pattern and the first upper pattern can be formed of polyimide (PI), polyacrylate, polyacetate, or the like. Further, the second lower pattern and the second upper pattern can be formed of silicon rubber such as polydimethylsiloxane (PDMS) or elastomer such as polyurethane (PU) or polytetrafluoroethylene (PTFE).

Next, referring to FIGS. 2 to 5B, a pixel PX including the plurality of sub pixels SP which is an individual unit emitting the light is disposed on the pixel plate patterns 121P. The plurality of sub pixels SP can form one pixel PX. n sub pixels SP which form one pixel PX can be disposed in each of the plurality of pixel plate patterns 121P. The plurality of sub pixels SP can include sub pixels SP which emit light with various colors, such as a red sub pixel, a green sub pixel, and a blue sub pixel.

In the meantime, in the drawing, it is illustrated that one pixel PX includes three sub pixels SP, but the number and a configuration of the plurality of sub pixels SP which forms one pixel PX are not limited thereto depending on a design of the display device 100.

Each of the plurality of sub pixels SP includes a light emitting diode 150 which is a display element and a pixel circuit for driving the light emitting diode 150.

The light emitting diode 150 can be configured by any one of various elements depending on a type of the display device 100. For example, when the display device 100 is an organic light emitting display device, the light emitting diode 150 can be an organic light emitting diode. When the display device 100 is an inorganic light emitting display device, the light emitting diode 150 can be a light emitting diode LED or a micro LED. Hereinafter, it is assumed that the light emitting diode 150 is a micro LED, but it is not limited thereto.

The pixel circuit supplies the driving current to the light emitting diode 150 to allow the light emitting diode 150 to emit light. The pixel circuit can include a plurality of transistors and capacitors. For example, the pixel circuit can include a plurality of transistors, such as a driving transistor DT or a switching transistor and a capacitor which is connected to any one of the plurality of transistors.

Referring to FIG. 4, a plurality of inorganic insulating layers is disposed on the plurality of pixel plate patterns 121P. For example, the plurality of inorganic insulating layers can include a multi-buffer layer 141, an active buffer layer 142, a gate insulating layer 143, a first interlayer insulating layer 144, and a second interlayer insulating layer 145. However, in addition to the above-described inorganic insulating layers, another inorganic insulating layer can be additionally disposed or one or more of the above-described inorganic insulating layers can be omitted. A configuration of the plurality of inorganic insulating layers is not limited thereto.

First, the multi-buffer layer 141 is disposed on the plurality of pixel plate patterns 121P and the active buffer layer 142 is disposed on the multi-buffer layer 141. The multi-buffer layer 141 and the active buffer layer 142 can reduce the permeation of moisture or impurities from the outside of the lower substrate 111 and the pixel plate pattern 121P. The multi-buffer layer 141 and the active buffer layer 142 can protect various components of the display device 100 from the moisture and oxygen of the outside. The multi-buffer layer 141 and the active buffer layer 142 are formed of an insulating material. For example, the multi-buffer layer 141 and the active buffer layer 142 are configured by a single layer or a double layer of silicon nitride (SiNx), silicon oxide (SiOx), and silicon oxynitride (SiON), but are not limited thereto. However, the multi-buffer layer 141 and the active buffer layer 142 can be omitted depending on a structure or a characteristic of the display device 100.

In the meantime, the multi-buffer layer 141 and the active buffer layer 142 can be formed only above the plurality of pixel plate patterns 121P and the plurality of second plate patterns 123. The multi-buffer layer 141 and the active buffer layer 142 can overlap the area in which the pixel plate patterns 121P and the second plate patterns 123 are disposed. The multi-buffer layer 141 and the active buffer layer 142 may not be formed in an area between the plurality of pixel plate patterns 121P and an area between the plurality of second plate patterns 123. The multi-buffer layer 141 and the active buffer layer 142 which are formed of an inorganic material can be easily cracked to be damaged during a process of stretching the display device 100. Therefore, the multi-buffer layer 141 and the active buffer layer 142 are patterned to have a shape of the plurality of pixel plate patterns 121P and the plurality of second plate patterns 123 to be formed only above the plurality of pixel plate patterns 121P and the plurality of second plate patterns 123. Accordingly, in the display device 100 according to the example embodiment of the present disclosure, the multi-buffer layer 141 and the active buffer layer 142 are formed only in an area overlapping the plurality of pixel plate patterns 121P and the plurality of second plate patterns 123 which are rigid patterns. Therefore, even though the display device 100 is bent or stretched to be deformed, the damage of the multi-buffer layer 141 and the active buffer layer 142 can be suppressed so that the damages of various components of the display device 100 can also be suppressed.

A light shielding layer BSM is disposed between the multi-buffer layer 141 and the active buffer layer 142, on the pixel plate pattern 121P. The light shielding layer BSM blocks light incident onto a semiconductor layer ACT of the driving transistor DT from the lower substrate 111. Light which is incident onto the semiconductor layer ACT of the driving transistor DT is blocked by the light shielding layer BSM to minimize a leakage current. The light shielding layer BSM can be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto.

A driving transistor DT is disposed on the active buffer layer 142. The driving transistor DT includes a semiconductor layer ACT, a gate electrode GE, a source electrode SE, and a drain electrode DE.

First, the semiconductor layer ACT is disposed on the active buffer layer 142. The semiconductor layer ACT can be formed of a semiconductor material, such as an oxide semiconductor, amorphous silicon, polysilicon, and an organic semiconductor, but is not limited thereto.

The gate insulating layer 143 is disposed on the semiconductor layer ACT. The gate insulating layer 143 is an insulating layer which insulates the semiconductor layer ACT from the gate electrode GE and can be configured by a single layer or a double layer of silicon oxide (SiOx) or silicon nitride (SiNx), but is not limited thereto.

The gate electrode GE is disposed on the gate insulating layer 143. The gate electrode GE can be configured by a conductive material, such as copper (Cu), aluminum (Al), molybdenum (Mo), nickel (Ni), titanium (Ti), chrome (Cr), or an alloy thereof, but is not limited thereto.

The first interlayer insulating layer 144 and the second interlayer insulating layer 145 are disposed on the gate electrode GE. The source electrode SE and the drain electrode DE are disposed on the second interlayer insulating layer 145. The source electrode SE and the drain electrode DE can be electrically connected to the semiconductor layer ACT through a contact hole formed in the second interlayer insulating layer 145, the first interlayer insulating layer 144, and the gate insulating layer 143. The source electrode SE and the drain electrode DE can be configured by a conductive material, such as copper (Cu), aluminum (Al), molybdenum (Mo), nickel (Ni), titanium (Ti), chrome (Cr), or an alloy thereof, but are not limited thereto.

Next, the first interlayer insulating layer 144 is disposed on the gate electrode GE and the second interlayer insulating layer 145 is disposed on the first interlayer insulating layer 144. The first interlayer insulating layer 144 and the second interlayer insulating layer 145 are insulating layers which protect components therebelow and can be configured by a single layer or a double layer of silicon oxide (SiOx) or silicon nitride (SiNx), but are not limited thereto.

In the meantime, the gate insulating layer 143, the first interlayer insulating layer 144, and the second interlayer insulating layer 145 are patterned to be the same as the multi-buffer layer 141 and the active buffer layer 142 to be formed only in an area overlapping the plurality of pixel plate patterns 121P and the plurality of second plate patterns 123. The gate insulating layer 143, the first interlayer insulating layer 144, and the second interlayer insulating layer 145 are also formed of the inorganic material, similar to the multi-buffer layer 141 and the active buffer layer 142. Therefore, when the gate insulating layer 143, the first interlayer insulating layer 144 and, the second interlayer insulating layer 145 are stretched while stretching the display device 100, the layers can be easily damaged. Therefore, the gate insulating layer 143, the first interlayer insulating layer 144, and the second interlayer insulating layer 145 are not formed in an area between the plurality of pixel plate patterns 121P and an area between the plurality of second plate patterns 123, but are patterned to have a shape of the plurality of pixel plate patterns 121P and the plurality of second plate patterns 123 to be formed only above the plurality of pixel plate patterns 121P and the plurality of second plate patterns 123. Accordingly, the plurality of inorganic insulating layers which is formed of an inorganic material to be vulnerable to stretching can be disposed only above the plurality of pixel plate patterns 121P and the plurality of second plate patterns 123 which are rigid substrates.

Next, a first conductive layer CL1 is disposed between the gate insulating layer 143 and the first interlayer insulating layer 144. The first conductive layers CL1 can configure at least a part of the plurality of wiring lines which supplies various signals to the sub pixel SPX or a configuration of the pixel circuit. For example, the first conductive layer CL1 can be any one of various wiring lines, such as a scan line, a data line, a reference line, an initialization line, a high potential power line VDDL, and a low potential power line VSSL. The first conductive layer CL1 can be configured by a conductive material, for example, any one of copper (Cu), aluminum (Al), molybdenum (Mo), nickel (Ni), titanium (Ti), and chrome (Cr), or an alloy thereof, and can be configured with a single layer or multi-layered structure, but is not limited thereto.

A second conductive layer CL2 is disposed between the first interlayer insulating layer 144 and the second interlayer insulating layer 145. The second conductive layer CL2 is an electrode which applies a voltage to the light shielding layer BSM. For example, the light shielding layer BSM is electrically connected to the source electrode SE of the driving transistor DT through the second conductive layer CL2 to be applied with a voltage. The light shielding layer BSM which is applied with a voltage by means of the second conductive layer CL2 does not operate as a floating gate and can minimize a fluctuation of a threshold voltage of the driving transistor DT which is generated by the floated light shielding layer BSM. The second conductive layer CL2 can be configured by a single layer or a multi-layered structure of a conductive material, such as copper (Cu), aluminum (Al), molybdenum (Mo), nickel (Ni), titanium (Ti), gold (Au), chrome (Cr), or an alloy thereof, but is not limited thereto.

A third conductive layer CL3 is disposed between the second interlayer insulating layer 145 and the planarization layer 146. The third conductive layer CL3 can configure at least a part of the plurality of wiring lines which supplies various signals to the sub pixel SP or a configuration of the pixel circuit. For example, the third conductive layer CL3 can be any one of various wiring lines, such as a scan line, a data line, a reference line, an initialization line, a high potential power line VDD, and a low potential power line VSS. The third conductive layer CL3 can be configured by a conductive material, for example, any one of copper (Cu), aluminum (Al), molybdenum (Mo), nickel (Ni), titanium (Ti), and chrome (Cr), or an alloy thereof, and can be configured with a single layer or multi-layered structure, but is not limited thereto.

In the meantime, another conductive layer can be further disposed between the first interlayer insulating layer 144 and the second interlayer insulating layer 145 and between the second interlayer insulating layer 145 and the planarization layer 146, but is not limited thereto.

A speaker power line SVSSL is disposed between the second interlayer insulating layer 145 and the planarization layer 146. The speaker power line SVSSL is a wiring line for transmitting a speaker power voltage SVSS to the sound unit 160 of the speaker area RAS. The speaker power line SVSSL can transmit a speaker power voltage SVSS to the first control electrode 161 of the sound unit 160 through the third connection line 133. The speaker power line SVSSL can be configured by a conductive material, for example, any one of copper (Cu), aluminum (Al), molybdenum (Mo), nickel (Ni), titanium (Ti), and chrome (Cr), or an alloy thereof, and can be configured with a single layer or multi-layered structure, but is not limited thereto.

Next, the planarization layer 146 is disposed on the driving transistor DT and the second interlayer insulating layer 145 in the pixel plate pattern 121P. The planarization layer 146 can planarize an upper portion of the pixel plate pattern 121P on which the driving transistor DT is disposed. The planarization layer 146 can be configured by a single layer or a plurality of layers and can be formed of an organic material. For example, the planarization layer 146 can be formed of an acrylic-based organic material, but is not limited thereto. Therefore, the planarization layer 146 can also be referred to as an organic insulating layer.

The planarization layer 146 can be disposed so as to cover top surfaces and side surfaces of the plurality of inorganic insulating layers on the plurality of pixel plate patterns 121P. The planarization layer 146 can be disposed so as to enclose the multi-buffer layer 141, the active buffer layer 142, the gate insulating layer 143, the first interlayer insulating layer 144, and the second interlayer insulating layer 145 which are inorganic insulating layers, together with the plurality of pixel plate patterns 121P. For example, the planarization layer 146 can be disposed so as to cover a side surface of the multi-buffer layer 141, a side surface of the active buffer layer 142, a side surface of the gate insulating layer 143, a side surface of the first interlayer insulating layer 144, a top surface and a side surface of the second interlayer insulating layer 145, and a part of a top surface of the pixel plate pattern 121P.

An inclination angle of the side surface of the planarization layer 146 can be formed to be smaller than an inclination angle formed by side surfaces of the multi-buffer layer 141, the active buffer layer 142, the gate insulating layer 143, the first interlayer insulating layer 144, and the second interlayer insulating layer 145. For example, the side surface of the planarization layer 146 can have a slope gentler than the slope of each of the side surface of the multi-buffer layer 141, the side surface of the active buffer layer 142, the side surface of the gate insulating layer 143, the side surface of the first interlayer insulating layer 144, and the side surface of the second interlayer insulating layer 145. Therefore, at least some of the connection line 130 which extends above the pixel plate pattern 121P along the side surface of the planarization layer 146 is disposed with a gentle slope so that when the display device 100 is stretched, the stress generated in the connection line 130 can be reduced. Therefore, the planarization layer 146 can compensate for the step on the side surface of each of the multi-buffer layer 141, the active buffer layer 142, the gate insulating layer 143, the first interlayer insulating layer 144, and the second interlayer insulating layer 145.

Further, the side surface of the planarization layer 146 has a relatively gentle slope so that the crack of the connection line 130 or separation thereof from the side surface of the planarization layer 146 can be suppressed. Accordingly, the planarization layer 146 having a gentle slope can enhance an adhesive strength with the connection line 130 disposed on the side surface of the planarization layer 146.

Next, a fourth conductive layer CL4 is disposed on the planarization layer 146 in the pixel plate pattern 121P. The fourth conductive layers CL4 can configure at least a part of the plurality of wiring lines which supplies various signals to the sub pixel SP or a configuration of the pixel circuit. For example, the fourth conductive layer CL4 can be any one of various wiring lines, such as a scan line, a data line, a reference line, an initialization line, a high potential power line VDD, and a low potential power line VSS. The fourth conductive layer CL4 can be configured by a conductive material, for example, any one of copper (Cu), aluminum (Al), molybdenum (Mo), nickel (Ni), titanium (Ti), and chrome (Cr), or an alloy thereof, and can be configured with a single layer or multi-layered structure, but is not limited thereto.

Referring to FIGS. 2 to 5A, a high potential power line VDDL and a low potential power line VSSL are disposed on the planarization layer 146. The high potential power line VDDL is a wiring line for transmitting the high potential power voltage VDD to the sub pixel SP and the low potential power line VSSL is a wiring line for transmitting the low potential power voltage VSS to the sub pixel SP. The high potential power lines VDDL on the plurality of pixel plate patterns 121P are electrically connected to each other by means of the first connection line 131 and the low potential power lines VSSL can be also electrically connected to each other by means of the first connection line 131. The high potential power lines VDDL and the low potential power lines VSSL can be configured by a conductive material, for example, any one of copper (Cu), aluminum (Al), molybdenum (Mo), nickel (Ni), titanium (Ti), and chrome (Cr), or an alloy thereof, and can be configured with a single layer or multi-layered structure, but is not limited thereto.

At this time, the low potential power line VSSL and the speaker power line SVSSL can be disposed as a double line shape on the pixel plate pattern 121P. The low potential power line VSSL and the speaker power line SVSSL can be disposed so at to at least partially overlap.

The first connection electrode CE1 and the second connection electrode CE2 are disposed on the planarization layer 146 in each of the plurality of sub pixels SP. The first connection electrode CE1 and the second connection electrode CE2 can be configured by a single layer or a multi-layered structure of a conductive material, such as copper (Cu), aluminum (Al), molybdenum (Mo), nickel (Ni), titanium (Ti), gold (Au), chrome (Cr), or an alloy thereof, but is not limited thereto.

The first connection electrodes CE1 is an electrode for electrically connecting the plurality of light emitting diodes 150 and the driving transistor DT. The first connection electrode CE1 can be electrically connected to any one of the source electrode SE or the drain electrode DE of the driving transistor DT through a contact hole formed in the planarization layer 146. Further, the first connection electrode CE1 can also be electrically connected to an electrode of the light emitting diode 150 through the conductive adhesive layer AD. Accordingly, the light emitting diode 150 and the driving transistor DT can be electrically connected by means of the first connection electrodes CE1.

The second connection electrode CE2 is an electrode for electrically connecting the light emitting diode 150 and the power line. The second connection electrode CE2 can be connected to any one of the high potential power line VDDL and the low potential power line VSSL. For example, the second connection electrode CE2 is integrally formed with any one of the high potential power line VDDL and the low potential power line VSSL to be electrically connected. Further, the second connection electrode CE2 can also be electrically connected to an electrode of the light emitting diode 150 through the conductive adhesive layer AD. Accordingly, the light emitting diode 150 and the power line can be electrically connected by means of the second connection electrodes CE2.

The light emitting diode 150 is disposed on the first connection electrode CE1 and the second connection electrode CE2 in each of the plurality of sub pixels SP. The light emitting diode 150 includes a first semiconductor layer 151, an emission layer 152, a second semiconductor layer 153, a first electrode 154, and a second electrode 155. The light emitting diode 150 of the display device 100 according to the example embodiment of the present disclosure has a flip-chip structure in which the first electrode 154 and the second electrode 155 are formed together on one surface of the emission layer 152.

The second semiconductor layer 153 is disposed on the first connection electrode CE1 and the second connection electrode CE2 and the first semiconductor layer 151 is disposed on the second semiconductor layer 153. The first semiconductor layer 151 and the second semiconductor layer 153 can be semiconductor layers doped with n-type and p-type impurities. For example, the first semiconductor layer 151 and the second semiconductor layer 153 can be layers doped with n-type and p-type impurities into a material such as gallium nitride (GaN), indium aluminum phosphide (InAlP), or gallium arsenide (GaAs). Further, the p-type impurity can be magnesium (Mg), zinc (Zn), beryllium (Be), and the like, and the n-type impurity can be silicon (Si), germanium, tin (Sn), and the like, but is not limited thereto.

The emission layer 151 is disposed between the first semiconductor layer 152 and the second semiconductor layer 153. The emission layer 152 is supplied with holes and electrons from the first semiconductor layer 151 and the second semiconductor layer 153 to emit light. For example, the emission layer 152 can be configured as a single layer or a multi-quantum well (MQW) structure. For example, the emission layer 152 can be configured by indium gallium nitride (InGaN), gallium nitride (GaN), or the like, but it is not limited thereto.

The first electrode 154 is disposed on the bottom surface of the first semiconductor layer 151. The first electrode 154 can be in contact with a bottom surface of the first semiconductor layer 152 which protrudes from the emission layer 152 and the second semiconductor layer 153. The first electrode 154 is an electrode for electrically connecting the first semiconductor layer 151 and the first connection electrode CE1 and is disposed between the first semiconductor layer 151 and the first connection electrode CE1. The first electrode 154 can be configured by any one of a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 155 is disposed on the bottom surface of the second semiconductor layer 153. The second electrode 155 is an electrode for electrically connecting the second semiconductor layer 153 and the second connection electrode CE2 and is disposed between the second semiconductor layer 153 and the second connection electrode CE2. The second electrode 155 can be configured by any one of a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, a conductive adhesive layer AD is disposed between the light emitting diode 150 and the first connection electrode CE1 and between the light emitting diode 150 and the second connection electrode CE2. The conductive adhesive layer AD can be a conductive adhesive layer AD in which conductive balls are dispersed in an insulating base member. When heat or pressure is applied to the conductive adhesive layer AD, the conductive balls are electrically connected in a portion applied with heat or pressure to have a conductive property and an area which is not pressurized can have an insulating property.

Therefore, the first electrode 154 and the second electrode 155 of the light emitting diode 150 can be electrically connected to the first connection electrode CE1 and the second connection electrode CE2 by means of the conductive adhesive layer AD. For example, after applying the conductive adhesive layer AD on the first connection electrode CE1 and the second connection electrode CE2, the light emitting diode 150 is transferred onto the conductive adhesive layer AD and the light emitting diode 150 is pressurized or heated. By doing this, the first connection electrode CE1 and the second connection electrode CE2 and the first electrode 154 and the second electrode 155 can be electrically connected. The remaining part of the conductive adhesive layer AD, excluding a part of the conductive adhesive layer AD disposed between the first electrode 154 and the first connection electrode CE1 and a part of the conductive adhesive layer AD disposed between the second electrode 155 and the second connection electrode CE2, can have an insulating property. Even though it is illustrated that the conductive adhesive layers AD which cover the first connection electrode CE1 and the second connection electrode CE2 are connected to each other in the drawing, the conductive adhesive layers AD can be separated to be disposed above the first connection electrode CE1 and the second connection electrode CE2, respectively.

Next, a bank 147 is disposed on the planarization layer 146. The bank 147 is disposed in an area between the plurality of sub pixels SP to minimize the color mixture between the plurality of sub pixels SP. The bank 147 is disposed so as to cover at least a part of the first connection electrode CE1, the second connection electrode CE2, the connection line 130, and the planarization layer 146. The bank 147 can be formed of an insulating material. Further, the bank 147 includes a black material to block wiring lines which can be visible through the active area AA. For example, the bank 147 can be formed of a carbon-based mixture and specifically, can include carbon black. However, it is not limited thereto and the bank 147 can be formed of a transparent insulating material. Even though in the drawing, it is illustrated that a height of the bank 147 is lower than a height of the light emitting diode 150, the present disclosure is not limited thereto. The height of the bank 147 can be equal to or higher than the height of the light emitting diode 150.

The upper substrate 112 is disposed on the light emitting diode 150 and the lower substrate 111. The upper substrate 112 is a substrate which supports various components disposed below the upper substrate 112. For example, the upper substrate 112 is formed as a film type and the film type upper substrate 112 can be attached onto the lower substrate 111 and the pattern layer 120.

The upper substrate 112 can be formed of the same material as the lower substrate 111. For example, the upper substrate 112 can be formed of a silicon rubber such as polydimethylsiloxane (PDMS) or an elastomer such as polyurethane (PU) or polytetrafluoroethylene (PTFE) and thus have a flexible property. However, the material of the upper substrate 112 is not limited thereto.

Next, referring to FIGS. 5A and 5B, a plurality of speaker plate patterns 121S is disposed on the lower substrate 111 and the sound unit 160 is disposed above each of the plurality of speaker plate patterns 121S. The sound unit 160 can be thin film type piezoelectric speaker. The sound unit 160 can vibrate the display device 100 to generate sounds and a finally generated sound can be supplied to a user. The sound unit 160 includes a first control electrode 161, an active layer 162, and a second control electrode 163.

First, the active layer 162 is disposed on the speaker plate pattern 121S. The active layer 162 can be formed of an electroactive polymer which is a polymer material which is deformed by an electric energy, for example, electrical stimulation. When an electric field is applied to the active layer 162, an alignment direction of dipoles in the active layer 162 is changed to generate electrostatic attraction or repulsion and vibration can be generated in the active layer 162. The active layer 162 can be formed of polyvinylidene difluoride (PVDF) based polymer. The PVDF is a semi-crystalline ferroelectric polymer which has a high elastic modulus, is lightweight, and has excellent flexibility, to have a strong resistance against the shock. Therefore, the sound unit 160 which is formed of PVDF having flexibility is applied to minimize a damage of the sound unit 160 according to the stretching operation of the display device 100.

A first control electrode 161 is disposed between the active layer 162 and the speaker plate pattern 121S. The first control electrode 161 is in contact with a bottom surface of the active layer 162 to apply an electric stimulus to the active layer 162. Referring to FIG. 5B, the first control electrode 161 is electrically connected to the speaker power line SVSSL through the third connection line 133 to be applied with the speaker power voltage SVSS. Therefore, the active layer 162 can be applied with the speaker power voltage SVSS through the first control electrode 161. The first control electrode 161 can be integrally formed with the connection line 130. The first control electrode 161 can be formed of a conductive material, and for example, a metal material such as copper (Cu), aluminum (Al), titanium (Ti), and molybdenum (Mo) or a stacked structure of metal materials such as copper/molybdenum-titanium (Cu/Moti) or titanium/aluminum/titanium (Ti/Al/Ti), but is not limited thereto.

In the speaker plate pattern 121S, the planarization layer 146 is disposed on the first control electrode 161 and the active layer 162 and the second control electrode 163 is disposed on the planarization layer 146. The second control electrode 163 is in contact with a top surface of the active layer 162 which is exposed from the planarization layer 146 to apply an electric stimulus to the active layer 162. Referring to FIG. 5A, the second control electrode 163 is electrically connected to the high potential power line VDDL through the third connection line 133 to be applied with the high potential power voltage VDD. Accordingly, instead of forming a new wiring line to drive the second control electrode 163, the existing high potential power line VDDL is utilized to simplify the structure of the display device 100.

The second control electrode 163 can be formed of a conductive material, and for example, a metal material such as copper (Cu), aluminum (Al), titanium (Ti), and molybdenum (Mo) or a stacked structure of metal materials such as copper/molybdenum-titanium (Cu/Moti) or titanium/aluminum/titanium (Ti/Al/Ti), but is not limited thereto.

The planarization layer 146 disposed on the speaker plate pattern 121S can be disposed to suppress a short between the first control electrode 161 and the second control electrode 163. The first control electrode 161 and the second control electrode 163 can be separated by the planarization layer 146. The planarization layer 146 is disposed on the first control electrode 161 and the active layer 162 and an opening through which the active layer 162 is exposed can be formed on the planarization layer 146. Therefore, the second control electrode 163 is electrically connected to the active layer 162 through the opening of the planarization layer 146, but is not in contact with the first control electrode 161 by the planarization layer 146.

The active layer 162 can be deformed by the speaker power voltage SVSS and the high potential power voltage VDD which are applied to the first control electrode 161 and the second control electrode 163, respectively. Accordingly, the active layer 162 of the sound unit 160 is deformed to vibrate the display device 100 embedded with the sound unit 160 and the sound can be output from the display device 100.

At this time, an intensity of vibration of each of the plurality of sound units 160 can be adjusted using a speaker power voltage SVSS which is applied to each sound unit 160 to implement a stereophonic sound. For example, the intensity of the vibration of the sound unit 160 can be adjusted by adjusting a voltage drop phenomenon of the speaker power voltage SVSS, a supplying location of the speaker power voltage SVSS, whether to output the speaker power voltage SVSS, an output timing, and an output time.

For example, the speaker power voltage SVSS can be applied to at least any one of both ends of the speaker power line SVSSL of the active area AA from the non-active area NA. For example, the speaker power voltage SVSS can flow from one end of the speaker power line SVSSL to the other end to be transmitted to the sound unit 160. For another example, the speaker power voltage SVSS can flow from the other end to one end to be transmitted to the sound unit 160. For example, the speaker power voltage SVSS applied to the speaker power line SVSSL on an outermost pixel plate pattern 121P adjacent to the non-active area NA is transmitted to the speaker power line SVSSL on the plurality of pixel plate patterns 121P disposed on the same row by means of the third connection line 133 and the first control electrode 161. However, the voltage drop phenomenon that the speaker power voltage VSS fluctuates due to the resistance of the wiring line can occur. Therefore, when the speaker power voltage SVSS is applied only to the speaker power line SVSSL at one end, among the plurality of speaker power lines SVSSL disposed on the same row, when the speaker power voltage SVSS is applied only to the speaker power line SVSSL at the other end, among the plurality of speaker power lines SVSSL disposed on the same row, and when the speaker power voltage SVSS is applied to both ends of the speaker power line SVSSL at one end and the other end, among the plurality of speaker power lines SVSSL disposed on the same row, intensities of vibrations of the plurality of sound units 160 can vary.

For example, when the speaker power voltage SVSS is applied to only one end of the speaker power line SVSSL in the non-active area NA, due to the voltage drop phenomenon, the intensity of vibration of the sound unit 160 adjacent to one end of the speaker power line SVSSL and the intensity of vibration of the sound unit 160 adjacent to the other end of the speaker power line SVSSL can be adjusted to be different. In contrast, when the speaker power voltage SVSS is applied to only the other end of the speaker power line SVSSL in the non-active area NA, the intensity of vibration of the sound unit 160 adjacent to the other end of the speaker power line SVSSL and the intensity of vibration of the sound unit 160 adjacent to one end of the speaker power line SVSSL can be adjusted to be different. Further, when the speaker power voltage SVSS is applied to one end and the other end of the speaker power line SVSSL in the non-active area NA, the intensity of vibration of the sound unit 160 adjacent to one end of the speaker power line SVSSL and the intensity of vibration of the sound unit 160 adjacent to the other end of the speaker power line SVSSL can be implemented to be the same. Accordingly, whether to output the speaker power voltage SVSS applied to one end and the other end of the plurality of speaker power lines SVSSL is adjusted to adjust the intensity of vibration of the sound unit 160.

The output timing and the output time of the speaker power voltage SVSS applied to one end and the other end of the speaker power lines SVSSL are adjusted to adjust the intensity of vibration of the sound unit 160 and implement a stereophonic sound. For example, the speaker power voltage SVSS is applied only to the speaker power line SVSSL located in a partial area of the display device 100, among the plurality of speaker power lines SVSSL to selectively drive only the sound unit 160 in a partial area. Further, the output time of the speaker power line SVSSL is configured to be different in each of the plurality of speaker power lines SVSSL to adjust the intensity of the vibration of the plurality of sound units 160 to be different to output the stereophonic sound. For example, the speaker power voltage SVSS is output to some speaker power line SVSSL for n minutes and the speaker power voltage SVSS is output to the other speaker power line SVSSL for m minutes to control the intensity of vibration of each of the plurality of sound units 160 connected to some speaker power line SVSSL and the other speaker power line SVSSL to be different.

Therefore, in the display device 100 according to the example embodiment of the present disclosure, whether to output the speaker power voltage SVSS to be applied to one end and the other end of the plurality of speaker power lines SVSSL, an output timing, and an output time are adjusted to output a stereophonic sound. For example, the speaker power voltage SVSS is selectively applied to one end and the other end of the plurality of speaker power lines SVSSL or the output time of the speaker power voltage SVSS can be adjusted to be different. Further, the speaker power voltage SVSS can be applied to each of the plurality of speaker power lines SVSSL at different timings. In this case, an application timing, an application period, and an intensity of the speaker power voltage SVSS applied to each of the plurality of sound units 160 can vary and a vibration intensity and a vibration period of the sound unit 160 can vary. Accordingly, in the display device 100 according to the example embodiment of the present disclosure, the plurality of sound units 160 can be driven in different manners using whether to output the speaker power voltage SVSS applied to the plurality of speaker power lines SVSSL, the output timing, the output period, and the output time to output the stereophonic sound.

Next, the plurality of connection lines 130 is disposed on the plurality of first line patterns 122 and the plurality of second line patterns 124. The plurality of connection lines 130 refers to wiring lines which electrically connect the configuration on the plurality of first plate patterns 121 and the configuration on the plurality of second plate patterns 123. For example, the plurality of connection lines 130 can extend to the plurality of first plate patterns 121 to be electrically connected to the plurality of wiring lines or the plurality of pads on the plurality of first plate patterns 121. The plurality of first line patterns 122 is not disposed in an area where the plurality of connection lines 130 is not disposed, among areas between the plurality of first plate patterns 121.

Further, the plurality of connection lines 130 is disposed on the plurality of second line patterns 124 of the non-active area NA to be electrically connected to the configuration on the plurality of second plate patterns 123 and the configuration on the plurality of first plate patterns 121.

The plurality of connection lines 130 can be formed of a conductive material, and for example, a metal material such as copper (Cu), aluminum (Al), titanium (Ti), and molybdenum (Mo) or a stacked structure of metal materials such as copper/molybdenum-titanium (Cu/Moti) or titanium/aluminum/titanium (Ti/Al/Ti), but is not limited thereto.

In the case of a general display device, various wiring lines such as a plurality of scan lines and a plurality of data lines are disposed to extend between the plurality of sub pixels with a straight line shape and the plurality of sub pixels is connected to one signal line. Therefore, in the general display device, various wiring lines, such as a scan line, a data line, a high potential voltage line, and a reference voltage line, extend from one side to the other side of the display device without being disconnected on the substrate.

In contrast, in the display device 100 according to the example embodiment of the present disclosure, various wiring lines, such as a scan line, a data line, a high potential voltage line, a reference voltage line, and an initialization voltage line having a straight line shape which are considered to be used for the general display device 100, is disposed only on the plurality of first plate patterns 121 and the plurality of second plate patterns 123. For example, in the display device 100 according to the example embodiment of the present disclosure, a straight line-shaped wiring line is disposed only on the plurality of first plate patterns 121 and the plurality of second plate patterns 123.

In the display device 100 according to the example embodiment of the present disclosure, the wiring lines or the pads on two adjacent first plate patterns 121 can be connected by the connection lines 130. Accordingly, the connection line 130 electrically connects the pads on two adjacent first plate patterns 121. Accordingly, the display device 100 according to the example embodiment of the present disclosure can include a plurality of connection lines 130 so as to electrically connect various wiring lines, such as a scan line, a data line, a high potential power line VDDL, a low potential power line VSSL, and a speaker power line SVSSL, between the plurality of first plate patterns 121.

For example, the scan line can be disposed on the plurality of pixel plate patterns 121P disposed to be adjacent in the first direction D1. At this time, the plurality of scan lines on the plurality of pixel plate patterns 121P adjacent to each other in the first direction D1 can be connected to each other by the first connection line 131 which serves as a scan line. Therefore, the scan line disposed on the plurality of pixel plate patterns 121P and the first connection line 131 disposed on the first line pattern 122 can serve as one scan line. Further, wiring lines which extend in the first direction D1, among all various wiring lines which can be included in the display device 100, such as an emission signal line, a low potential power line VSSL, and a high potential power line VDDL, can also be electrically connected by the first connection line 131, as described above.

Referring to FIGS. 2 and 3, the plurality of connection lines 130 includes a first connection line 131, a second connection line 132, and a third connection line 133.

The first connection line 131 and the second connection line 132 are disposed between the plurality of pixel plate patterns 121P, between the plurality of second plate patterns 123, and between the plurality of pixel plate patterns 121P and the plurality of second plate patterns 123. The third connection line 133 is disposed between the plurality of pixel plate patterns 121P and the plurality of speaker plate patterns 121S. Specifically, the first connection line 131 refers to a wiring line extending in the first direction D1 between the plurality of first plate patterns 121, between the plurality of second plate patterns 123, and between the plurality of first plate patterns 121 and the plurality of second plate patterns 123, among the connection lines 130. The second connection line 132 refers to a wiring line extending in the second direction D2 between the plurality of first plate patterns 121, between the plurality of second plate patterns 123, and between the plurality of first plate patterns 121 and the plurality of second plate patterns 123. Further, the third connection line 133 refers to a wiring line extending in a direction different from the first direction D1 and the second direction D2 between the plurality of pixel plate patterns 121P and the speaker plate patterns 121S, for example, in an inclined direction to the first direction D1 and the second direction D2. Here, the first direction D1 and the second direction D2 can also be referred to as a row direction and a column direction, respectively.

The plurality of first connection lines 131 extends in the first direction D1 between the plurality of first plate patterns 121 and can electrically connect the plurality of pads or the plurality of wiring lines disposed on the plurality of first plate patterns 121. The first connection line 131 is disposed on the first line pattern 122 extending in the first direction D1 between the plurality of first plate patterns 121, among the plurality of first line patterns 122. The first connection line 131 extends to the first plate pattern 121 from the first line pattern 122 to be connected to the plurality of pads or wiring lines on the first plate pattern 121. For example, the first connection line 131 can electrically connect the scan line, the emission control line, the high potential power line VDDL, and the low potential power line VSSL, on one pair of pixel plate patterns 121P which are adjacent to each other in the first direction D1. Therefore, the first connection line 131 can serve as a scan line, an emission control line, a high potential power line VDDL, and a low potential power line VSSL.

The second connection lines 132 extend in the second direction D2 between the plurality of first plate patterns 121 and electrically connect the plurality of wiring lines disposed on the plurality of first plate patterns 121. The second connection line 132 is disposed on the first line pattern 122 extending in the second direction D2 between the plurality of first plate patterns 121, among the plurality of first line patterns 122. The second connection line 132 extends to the upper portion of the first plate pattern 121 from the first line pattern 122 to be connected to any one of the plurality of pads or the plurality of wiring lines on the first plate pattern 121. For example, the second connection line 132 can electrically connect the data lines and the reference lines on one pair of pixel plate patterns 121P which are adjacent to each other in the second direction D2. Accordingly, the second connection line 132 can serve as a data line and a reference line.

The third connection lines 133 extend in a direction which is different from the first direction D1 and the second direction D2, for example, an inclined direction to the first direction D1 and the second direction D2, between the plurality of first plate patterns 121 and electrically connect the plurality of wiring lines or pads disposed on the plurality of first plate patterns 121. The third connection line 133 can electrically connect the speaker power line SVSSL and the high potential power line VDDL on the pixel plate pattern 121P to the first control electrode 161 and the second control electrode 163 on the speaker plate pattern 121S, respectively. The third connection line 133 extends from any one of four corners of the pixel plate pattern 121P in an inclined direction to the first direction D1 and the second direction D2 to be electrically connected to the first control electrode 161 or the second control electrode 163 on the speaker plate pattern 121S. The third connection line 133 can be connected to at least a part of four corners of one pixel plate pattern 121P. Further, the third connection line 133 can be connected to at least a part of four corners of one speaker plate pattern 121S.

For example, referring to FIGS. 2 and 3, the third connection line 133 disposed between a right lower corner of one pixel plate pattern 121P and a left upper corner of the speaker plate pattern 121S can electrically connect the high potential power line VDDL on the pixel plate pattern 121P and the second control electrode 163 on the speaker plate pattern 121S. Therefore, the high potential power voltage VDD can be transmitted to the second control electrode 163 of the sound unit 160 through the third connection line 133.

The third connection line 133 disposed between a right upper corner of one pixel plate pattern 121P and a left lower corner of the speaker plate pattern 121S and the third connection line 133 disposed between a left upper corner of one pixel plate pattern 121P and a right lower corner of the speaker plate pattern 121S can electrically connect the speaker power line SVSSL on the pixel plate pattern 121P and the first control electrode 161 on the speaker plate pattern 121S. The third connection line 133 connected to the speaker power line SVSSL can serve as a speaker power line SVSSL. Therefore, the speaker power voltage SVSS can be transmitted to the first control electrode 161 of the sound unit 160 through the third connection line 133.

In the meantime, referring to FIGS. 2 and 3, the high potential power lines VDDL on the pixel plate pattern 121P can be connected by the first connection line 131. For example, four first connection lines 131 are disposed between one pair of adjacent pixel plate patterns 121P and can serve as wiring lines which connect a low potential power line VSSL, the scan line, the emission control line, and the high potential power line VDDL, respectively. The high potential power lines VDDL on the plurality of pixel plate patterns 121P is already electrically connected to each other by the first connection line 131 so that the number of third connection lines 133 disposed between the high potential power line VDDL and the second control electrode 163 can be designed to vary.

For example, as illustrated in FIG. 2, the high potential power voltage VDD is transmitted from the high potential power line VDDL on the pixel plate pattern 121P to the second control electrode 163 of the speaker plate pattern 121S using one third connection line 133. For example, the third connection line 133 connected to the high potential power line VDDL can be used only to transmit the high potential power voltage VDD to the second control electrode 163. As another example, as illustrated in FIG. 3, the high potential power line VDDL on one pair of adjacent pixel plate patterns 121P and the second control electrode 163 can be electrically connected using one pair of third connection lines 133. One pair of third connection lines 133 transmits the high potential power voltage VDD to the second control electrode 163 and connects the high potential power lines VDDL on adjacent pixel plate patterns 121P. Therefore, one pair of third connection lines can serve as high potential power lines VDDL. Accordingly, as illustrated in FIG. 2, when one third connection line 133 is formed to electrically connect the high potential power line VDDL and the second control electrode 163, the number of third connection lines 133 is reduced to simplify the structure of the display device 100. Further, as illustrated in FIG. 3, when one pair of third connection lines 133 is formed to electrically connect one pair of high potential power lines VDDL and the second control electrode 163, the high potential power voltage VDD can be more easily transmitted to the second control electrode 163.

Further, as described above, four first connection lines 131 which connect the low potential power line VSSL, the scan line, the emission control line, and the high potential power line VDDL are disposed between one pair of adjacent pixel plate patterns 121P. However, since the area of the malleable area SA between one pair of adjacent pixel plate patterns 121P is limited, it can be difficult to additionally form the first connection line 131 which connects the speaker power lines SVSSL on the pixel plate patterns 121P. Therefore, in the display device 100 according to one example embodiment of the present disclosure, the speaker power lines SVSSL on one pair of adjacent pixel plate patterns 121P can be electrically connected using the third connection line 133. One pair of third connection lines 133 connected to the left lower corner and the right lower corner of the speaker plate pattern 121S can be connected to the speaker power lines SVSSL on one pair of adjacent pixel plate patterns 121P. Further, one pair of third connection lines 133 can be electrically connected by means of the first control electrode 161 of the sound unit 160. Accordingly, the speaker power lines SVSSL can be electrically connected to each other using the third connection line 133, without additionally forming the first connection line 131. Therefore, the speaker power voltage SVSS can be transmitted to the first control electrode 161 of the sound unit 160 through a signal path illustrated in FIGS. 2 and 3, for example, a signal path on the pixel plate pattern 121P, the third connection line 133, and the speaker plate pattern 121S.

In the meantime, an adhesive layer can be further disposed between the lower substrate 111 and the pattern layer 120. The adhesive layer is a layer for bonding the lower substrate 111 and the pattern layer 120. When the display device 100 is formed, after sequentially forming the pattern layer 120, a configuration of the plurality of sub pixels SP, and a configuration of the sound unit 160 on a rigid temporary substrate, the rigid temporary substrate and the pattern layer 120 are separated and the lower substrate 111 can be attached below the pattern layer 120. At this time, in order to fix the pattern layer 120 and the lower substrate 111, the adhesive layer can be disposed between the pattern layer 120 and the lower substrate 111. For example, the adhesive layer can be an optically clear adhesive (OCA), but is not limited thereto.

In the display device 100 according to the example embodiment of the present disclosure, the sound unit 160 can be formed in the display device 100 using an empty space between the pixel plate pattern 121P and the first connection line 131 and the second connection line 132. In the active area AA, the plurality of sub pixels is disposed in a matrix while forming a plurality of rows and a plurality of columns. The plurality of pixel plate patterns 121P in which the plurality of sub pixels SP is formed and the plurality of first line patterns 122 and the plurality of connection lines 130 are formed between the plurality of pixel plate patterns 121P to display images. At this time, a diagonal direction of each of the plurality of pixel plate patterns 121P is an empty space and the sound unit 160 is formed in the empty space so that the speaker can be embedded in the display device 100. The sound unit 160 includes an active layer 162 and a first control electrode 161 and a second control electrode 163 on both surfaces of the active layer 162 and the first control electrode 161 and the second control electrode 163 can be applied with a voltage through a third connection line 133 which is stretchable. Accordingly, the sound unit 160 is formed in the display device 100 so that the display device 100 itself can output a stereophonic sound.

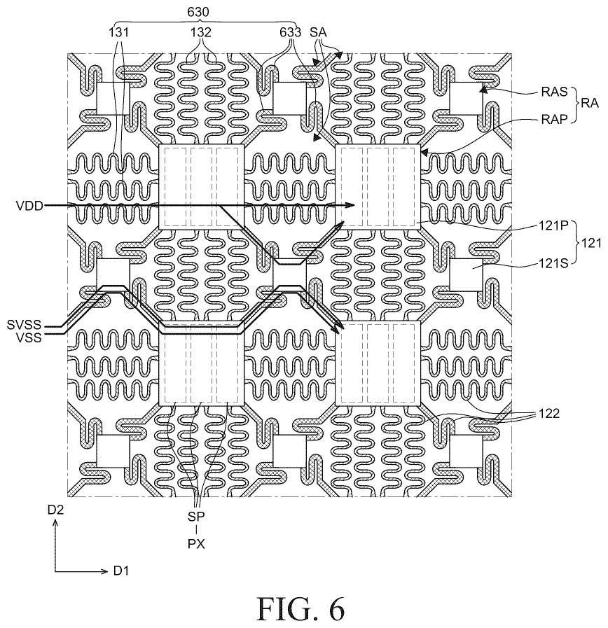

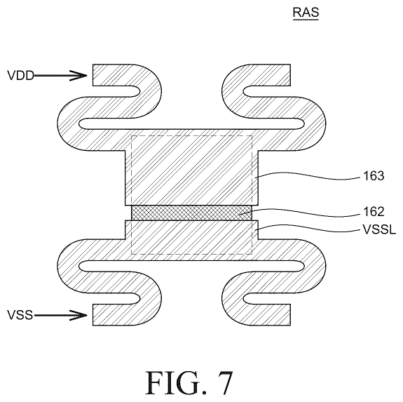

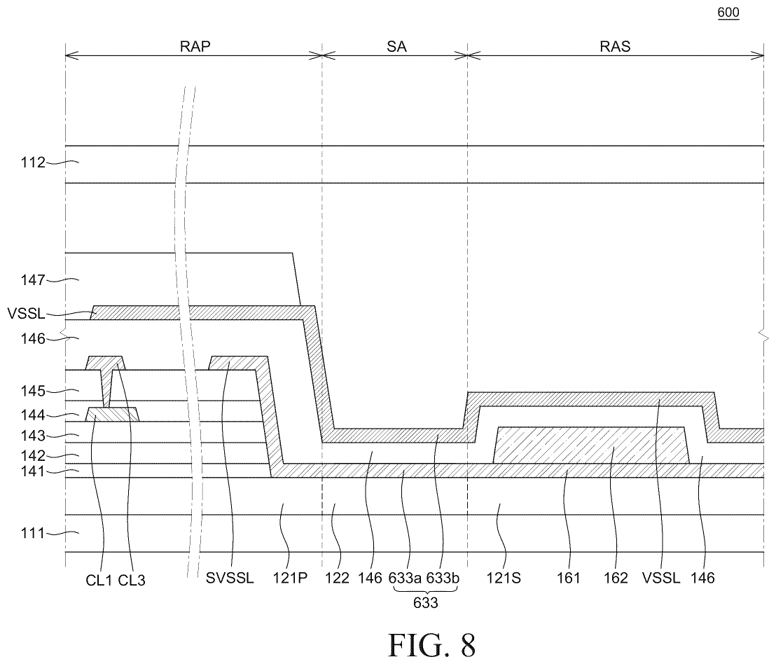

FIG. 6 is an enlarged plan view of an active area of a display device according to another example embodiment of the present disclosure. FIG. 7 is a schematic plan view of a speaker area of a display device according to another example embodiment of the present disclosure. FIG. 8 is a cross-sectional view of a display device according to another example embodiment of the present disclosure. In FIG. 7, for the convenience of description, only a low potential power line VSSL, an active layer 162 and a second control electrode 163 of a sound unit 160 are illustrated. A configuration of a display device 600 of FIGS. 6 to 8 is the same as or substantially the same as that of the display device 100 of FIGS. 1 to 5B except for a connection line 630 and a low potential power line VSSL so that a redundant description will be omitted or may be briefly provided.

Referring to FIGS. 6 to 8, the low potential power line VSSL and the speaker power line SVSSL overlap each other to be disposed as a double line shape on the pixel plate pattern 121P. A 3-1-th connection line 633a connected to the speaker power line SVSSL and a 3-2-th connection line 633b connected to the low potential power line VSSL overlap each other to be disposed as a double line shape on the first wiring line pattern 122.

First, the low potential power line VSSL is disposed above each of the plurality of pixel plate patterns 121P and the plurality of speaker plate patterns 121S. The low potential power line VSSL can be disposed on the planarization layer 146 on the pixel plate pattern 121P. The low potential power line VSSL can be disposed on the active layer 162 and the planarization layer 146 on the speaker plate pattern 121S.

The speaker power line SVSSL is disposed on the plurality of pixel plate patterns 121P and the first control electrode 161 of the sound unit 160 which is electrically connected to the speaker power line SVSSL is disposed on the plurality of speaker plate patterns 121S. The speaker power line SVSSL can be disposed below the planarization layer 146 on the pixel plate pattern 121P. The first control electrode 161 which is electrically connected to the speaker power line SVSSL can be disposed below the active layer 162 on the speaker plate pattern 121S.

The low potential power line VSSL and the speaker power line SVSSL overlap each other on the pixel plate pattern 121P with the planarization layer 146 therebetween. The first control electrode 161 which is electrically connected to the speaker power line SVSSL and the low potential power line VSSL overlap each other on the speaker plate pattern 121S with the active layer 162 therebetween. Therefore, the speaker power line SVSSL to which the speaker power voltage SVSS is applied, the first control electrode 161 and the low potential power line VSSL to which the low potential power voltage VSS is applied can be disposed to overlap each other in the pixel plate pattern 121P and the speaker plate pattern 121S.

The third connection line 633 includes a 3-1-th connection line 633a and a 3-2-th connection line 633b which are disposed on the same first line pattern 122 to overlap each other. The 3-1-th connection line 633a is a wiring line which electrically connects the speaker power line SVSSL and the first control electrode 161 on the plurality of pixel plate patterns 121P and the plurality of speaker plate patterns 121S. The 3-2-th connection line 633b is a wiring line which electrically connects the low potential power lines VSSL on the plurality of pixel plate patterns 121P and the plurality of speaker plate patterns 121S. The 3-1-th connection line 633a is disposed on the first line pattern 122 and the 3-2-th connection line 633b can be disposed on the 3-1-th connection line 633a.

The planarization layer 146 is disposed between the 3-1-th connection line 633a and the 3-2-th connection line 633b to suppress the defect that the 3-1-th connection line 633a and the 3-2-th connection line 633b are shorted. The planarization layer 146 extends onto the first wiring pattern 122 and the speaker plate pattern 121S from the pixel plate pattern 121P to separate the low potential power line VSSL from the speaker power line SVSSL and the first control electrode 161.

Referring to FIG. 7, the second control electrode 163 to which the high potential power voltage VDD is applied and the low potential power line VSSL can be disposed together on the active layer 162 in the speaker plate pattern 121S. The high potential power line VDDL and the low potential power line VSSL can be disposed to be spaced apart from each other on the active layer 162. Further, an opening which overlaps only the high potential power line VDDL is formed in the planarization layer 146 disposed between the active layer 162 and the high potential power line VDDL and between the active layer 162 and the low potential power line VSSL so that the low potential power line VSSL is not connected to the active layer 162. Accordingly, the planarization layer including the opening which overlaps only the high potential power line VDDL is formed on the active layer 162 to suppress the defect that the low potential power line VSSL is connected to the high potential power line VDDL or the active layer 162.

Accordingly, in the display device 600 according to another example embodiment of the present disclosure, the plurality of low potential power lines VSSL is electrically connected to each other using the third connection line 633 to reduce the number of first connection lines 131. The low potential power voltage VSS needs to be applied to the plurality of sub pixels SP on the pixel plate pattern 121P so that the low potential power line VSSL is disposed on the pixel plate pattern 121P, which are electrically connected to each other through the first connection line 131 disposed between the pixel plate patterns 121P. However, in the display device 600 according to another example embodiment of the present disclosure, the low potential power line VSSL is formed also on the speaker plate pattern 121S. The low potential power lines VSSL on the pixel plate pattern 121P can be electrically connected by means of the third connection line 633 and the low potential power line VSSL on the speaker plate pattern 121S. Therefore, the low potential power voltage VSS detours the speaker area RAS to be transmitted to the plurality of low potential power lines VSSL. Accordingly, the first connection line 131 for connecting the plurality of low potential power lines VSSL of the pixel plate pattern 121P can be deleted and the structure of the connection line 630 can be simplified.

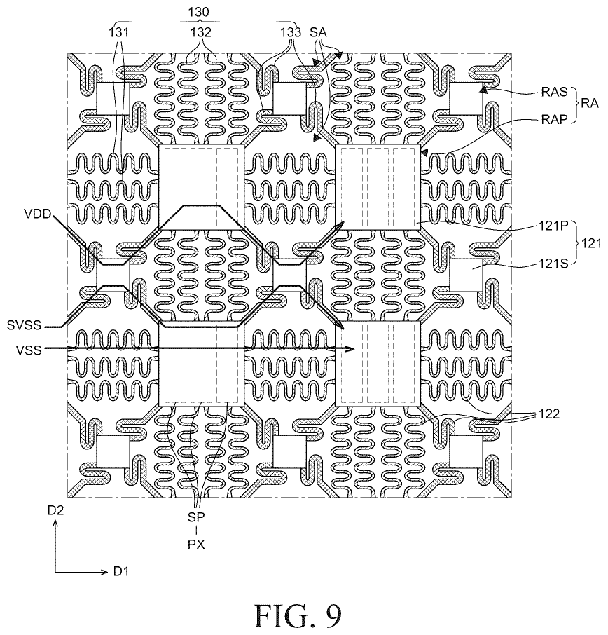

FIG. 9 is an enlarged plan view of an active area of a display device according to still another example embodiment of the present disclosure. A configuration of a display device 900 of FIG. 9 is the same as or substantially the same as that of the display device 100 of FIGS. 1 to 5B except for a connection line 130 and a high potential power line VDDL so that a redundant description will be omitted or may be briefly provided.

Referring to FIG. 9, the high potential power lines VDDL on the pixel plate pattern 121P can be connected by the third connection line 133. For example, three first connection lines 131 are disposed between one pair of adjacent pixel plate patterns 121P and can serve as wiring lines which connect a low potential power line VSSL, the scan line, and the emission control line, respectively. The high potential power line VDDL on the plurality of pixel plate patterns 121P can be electrically connected to each other by means of the third connection line 133 and the second control electrode 163 of the sound unit 160, instead of the first connection line 131.

For example, the high potential power line VDDL is disposed on the plurality of pixel plate patterns 121P and one of the plurality of high potential power lines VDDL can be electrically connected to the second control electrode 163 on the speaker plate pattern 121S through one third connection line 133. Further, the second control electrode 163 can be electrically connected to another high potential power line VDDL on an adjacent pixel plate pattern 121P by means of another third connection line 133. Accordingly, the plurality of high potential power lines VDDL can be connected to each other by means of the third connection line 133 and the second control electrode 163 and the high potential power voltage of the plurality of high potential power lines VDDL detours the plurality of speaker areas RAS to be transmitted to the plurality of pixel areas RAP.

Therefore, even though the first connection line 131 for connecting the high potential power lines VDDL to each other is not formed between the pixel plate patterns which are adjacent to each other in the first direction D1, the high potential power voltage VDD can be easily transmitted to the plurality of high potential power lines VDDL.

Accordingly, in the display device 900 according to still another example embodiment of the present disclosure, the plurality of high potential power lines VDDL is electrically connected to each other using the third connection line 133 and the second control electrode 163 to reduce the number of first connection lines 131. The second control electrode 163 on the speaker plate pattern 121S is applied with the high potential power voltage VDD to deform the active layer 162. Therefore, the high potential power lines VDDL on the plurality of pixel plate patterns 121P are electrically connected to each other by means of the second control electrode 163 and the third connection line 133 on the speaker plate pattern 121S to transmit the high potential power voltage VDD to the plurality of high potential power lines VDDL. Therefore, the high potential power voltage VDD detours the speaker area RAS to be transmitted to the plurality of high potential power lines VDDL. Accordingly, the first connection line 131 for connecting the high potential power lines VSSL on the pixel plate pattern 121P can be deleted and the structure of the connection line 130 can be simplified.

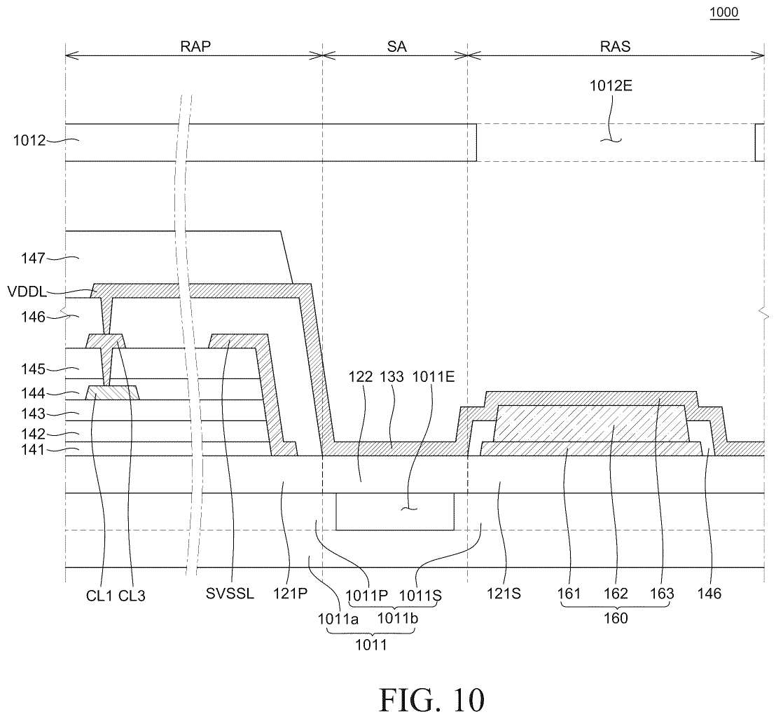

FIG. 10 is a cross-sectional view of a display device according to still another example embodiment of the present disclosure. A configuration of a display device 1000 of FIG. 10 is the same as or substantially the same as that of the display device 100 of FIGS. 1 to 5B except for a lower substrate 1011 and an upper substrate 1012 so that a redundant description will be omitted or may be briefly provided.

Referring to FIG. 10, the lower substrate 1011 includes a base layer 1011a and a pattern support layer 1011b on the base layer 1011a. The base layer 1011a and the pattern support layer 1011b can be integrally formed. The pattern support layer 1011b includes a plurality of pixel support layers 1011P which supports the plurality of pixel plate patterns 121P and a plurality of speaker support layers 1011S which supports the plurality of speaker plate patterns 121S. Further, the pattern support layer 1011b of the lower substrate 1011 includes a first opening 1011E formed between the plurality of pixel support layers 1011P and the plurality of speaker support layers 1011S.

First, the base layer 1011a of the lower substrate 1011 can support and protect various components of the display device 1000. The base layer 1011a is formed in the entire display device 1000 to support the pattern layer 120, the configuration of the sub pixel SP, and the configuration of the sound unit 160 formed on the base layer 1011a.

The pattern support layer 1011b is disposed between the base layer 1011a and the pattern layer 120. The pattern support layer 1011b is a layer which supports the plurality of first plate patterns 121 and can support the plurality of first plate patterns 121 together with the base layer 1011a.

The plurality of pixel support layers 1011P of the pattern support layer 1011b is disposed so as to overlap the plurality of pixel plate patterns 121P. The plurality of pixel support layers 1011P is disposed in the pixel area RAP to be in contact with at least a part of the pixel plate pattern 121P. The plurality of pixel support layers 1011P can support the plurality of pixel plate patterns 121P.

The plurality of speaker support layers 1011S of the pattern support layer 1011b is disposed so as to overlap the plurality of speaker plate patterns 121S. The plurality of speaker support layers 1011S is disposed in the speaker area RAS to be in contact with at least a part of the speaker plate pattern 121S. The plurality of speaker support layers 1011S can support the plurality of speaker plate patterns 121S.

A plurality of first openings 1011E is disposed between the plurality of pixel support layers 1011P and the speaker support layers 1011S of the pattern support layer 1011b. The plurality of first openings 1011E can be disposed so as to overlap the malleable area SA in which the connection line 130 is disposed. The first opening 1011E is a groove formed by patterning the pattern support layer 1011b and a top surface of the base layer 1011a can be exposed from the first opening 1011E. In the first opening 1011E, the first line pattern 122 and the base layer 1011a can be disposed to be spaced apart from each other and an empty space can be formed between the first line pattern 122 and the base layer 1011a. Each of the plurality of first openings 1011E can be disposed so as to enclose the speaker plate pattern 121S in the planar view. For example, only one first opening 1011E can be disposed in the malleable area SA which encloses one speaker plate pattern 121S. For example, a plurality of first openings 1011E can be disposed in the malleable area SA which encloses one speaker plate pattern 121S, but is not limited thereto.

In the meantime, even though in the drawing, it is illustrated that the first opening 1011E is disposed in the malleable area SA, at least a part of the first opening 1011E can be disposed to extend to the speaker area RAS in the malleable area SA. In this case, an outer part of the speaker plate pattern 121S overlaps the first opening 1011E and an inner part of the speaker plate pattern 121S can be in contact with the speaker support layer 1011S.

Next, the upper substrate 1012 includes a plurality of second openings 1012E. The plurality of second openings 1012E can be openings which pass through the upper substrate 1012. The plurality of second openings 1012E can overlap the speaker area RAS. At least some of the plurality of second openings 1012E can be disposed so as to overlap the sound unit 160. The plurality of first openings 1011E and the plurality of second openings 1012E are alternately disposed in the planar view. The plurality of first openings 1011E and the plurality of second openings 1012E at least partially overlap in the planar view. As the plurality of second openings 1012E which is disposed to be spaced apart from each other is formed on the upper substrate 1012, a planar shape of the upper substrate 1012 can be formed to have a mesh shape. Accordingly, the upper substrate 1012 is patterned in the plurality of second openings 1012E so that the sound unit 160 can be exposed to the outside.

In the meantime, a lower substrate 1011 and an upper substrate 1012 of the display device 1000 according to still another example embodiment of the present disclosure can be applied to the display device 100 of FIGS. 1 to 5B, the display device 600 of FIGS. 6 to 8, and the display device 900 of FIG. 9, respectively.

In the display device 1000 according to still another example embodiment of the present disclosure, the first opening 1011E and the second opening 1012E can configure an enclosure which amplifies and outputs a sound of the sound unit 160. A space for resonating a sound generated in the sound unit 160 is ensured by the first opening 1011E and the second opening 1012E formed by patterning at least a part of the lower substrate 1011 and the upper substrate 1012 and a larger sound can be output even with an output with a smaller intensity. Further, in the second opening 1012E, a front surface of the sound unit 160 is exposed so that the sound generated in the sound unit 160 can be more easily output to the outside of the display device 1000. Accordingly, in the display device 1000 according to still another example embodiment of the present disclosure, at least a part of the lower substrate 1011 and the upper substrate 1012 is patterned to amplify the sound of the sound unit 160 and more easily output the sound to the outside of the display device 1000.

The example embodiments of the present disclosure can also be described as follows:

According to an aspect of the present disclosure, a display device includes a stretchable lower substrate, a plurality of pixel plate patterns disposed to be spaced apart from each other on the lower substrate and having a plurality of sub pixels, a plurality of speaker plate patterns disposed to be spaced apart from each other on the lower substrate and alternately disposed with the plurality of pixel plate patterns, a plurality of connection lines disposed between the plurality of pixel plate patterns and between the plurality of pixel plate patterns and the plurality of speaker plate patterns, and a sound unit disposed on each of the plurality of speaker plate patterns.

The sound unit can include a first control electrode disposed on each of the plurality of speaker plate patterns, an active layer disposed on the first control electrode, and a second control electrode disposed on the active layer. Further, the active layer can be formed of an electroactive polymer deformed by an electric energy.

The display device can further include a high potential power line disposed on the plurality of pixel plate patterns, and a speaker power line disposed on the plurality of pixel plate patterns. The speaker power line can be electrically connected to the first control electrode by the plurality of connection lines, and the high potential power line can be electrically connected to the second control electrode by the plurality of connection lines.

The display device can further include a planarization layer disposed between the high potential power line and the speaker power line in the plurality of pixel plate patterns and disposed between the active layer and the second control electrode in the plurality of speaker plate patterns, and the planarization layer can include an opening which overlaps with the active layer and the second control electrode.

The display device can further include a low potential power line disposed on the planarization layer in the plurality of pixel plate patterns, and at least a part of the low potential power line can overlap with the speaker power line.

The plurality of connection lines can include a first connection line disposed between the plurality of pixel plate patterns and extending in a first direction, a second connection line disposed between the plurality of pixel plate patterns and extending in a second direction which is different from the first direction, and a third connection line disposed between the plurality of pixel plate patterns and the plurality of speaker plate patterns and extending in a direction different from the first direction and the second direction.

The high potential power lines disposed on the plurality of pixel plate patterns can be electrically connected by the first connection line and the third connection line.

The high potential power lines disposed on the plurality of pixel plate patterns can be electrically connected by the third connection line and the second control electrode.

The low potential power lines disposed on the plurality of pixel plate patterns can be electrically connected to the third connection line.

The low potential power line can be further disposed on the planarization layer and the active layer in the plurality of speaker plate patterns, the low potential power line and the second control electrode can be disposed to be spaced apart from each other in the plurality of speaker plate patterns, and the active layer can be spaced apart from the low potential power line with the planarization layer therebetween.

The low potential power lines disposed on the plurality of pixel plate patterns and the low potential power lines disposed on the plurality of speaker plate patterns can be electrically connected by the third connection line.

The third connection line can include a 3-1-th connection line electrically connecting the speaker power line on the plurality of pixel plate patterns and the first control electrode, and a 3-2-th connection line disposed so as to overlap the 3-1-th connection line and electrically connecting the low potential power lines on the plurality of pixel plate patterns and the low potential power lines on the plurality of speaker plate patterns, where a planarization layer can be disposed between the 3-1-th connection line and the 3-2-th connection line.

The lower substrate can include a base layer, and a pattern support layer disposed between the base layer and the plurality of pixel plate patterns and between the base layer and the plurality of speaker plate patterns, and the pattern support layer can include a plurality of pixel support layers which overlaps with the plurality of pixel plate patterns, and a plurality of speaker supports layers which overlaps with the plurality of speaker plate patterns.

The pattern support layer of the lower substrate can further include a plurality of first openings disposed between the plurality of pixel support layers and the plurality of speaker support layers, the plurality of first openings can be grooves formed by patterning the pattern support layers and a top surface of the base layer can be exposed from the plurality of first openings and the plurality of connection lines and the base layer can be disposed to be spaced apart from each other in the plurality of first openings.

The display device can further include an upper substrate disposed on the sound unit and the plurality of pixel plate patterns and having a plurality of second openings, and the plurality of second openings can be openings which pass through the upper substrate and at least a part of the plurality of second openings can overlap with the sound unit.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a stretchable lower substrate;
a plurality of pixel plate patterns disposed to be spaced apart from each other on the lower substrate, the plurality of pixel plate patterns including a plurality of sub pixels;
a plurality of speaker plate patterns disposed to be spaced apart from each other on the lower substrate, and alternately disposed with the plurality of pixel plate patterns;
a plurality of connection lines disposed between the plurality of pixel plate patterns and between the plurality of pixel plate patterns and the plurality of speaker plate patterns; and
a sound unit disposed on each of the plurality of speaker plate patterns.

2. The display device according to claim 1, wherein the sound unit includes:
a first control electrode disposed on each of the plurality of speaker plate patterns;
an active layer disposed on the first control electrode; and
a second control electrode disposed on the active layer, and
wherein the active layer includes an electroactive polymer deformed by an electric energy.

3. The display device according to claim 2, further comprising:
a high potential power line disposed on the plurality of pixel plate patterns; and
a speaker power line disposed on the plurality of pixel plate patterns,
wherein the speaker power line is electrically connected to the first control electrode by the plurality of connection lines, and the high potential power line is electrically connected to the second control electrode by the plurality of connection lines.

4. The display device according to claim 3, further comprising:
a planarization layer disposed between the high potential power line and the speaker power line in the plurality of pixel plate patterns and disposed between the active layer and the second control electrode in the plurality of speaker plate patterns,
wherein the planarization layer includes an opening overlapping with the active layer and the second control electrode.

5. The display device according to claim 4, further comprising:
a low potential power line disposed on the planarization layer in the plurality of pixel plate patterns,
wherein at least a part of the low potential power line overlaps with the speaker power line.

6. The display device according to claim 5, wherein the plurality of connection lines include:
a first connection line disposed between the plurality of pixel plate patterns and extends in a first direction;
a second connection line disposed between the plurality of pixel plate patterns and extends in a second direction being different from the first direction; and
a third connection line disposed between the plurality of pixel plate patterns and the plurality of speaker plate patterns and extending in a direction different from the first direction and the second direction.

7. The display device according to claim 6, wherein the high potential power lines disposed on the plurality of pixel plate patterns are electrically connected by the first connection line and the third connection line.

8. The display device according to claim 6, wherein the high potential power lines disposed on the plurality of pixel plate patterns are electrically connected by the third connection line and the second control electrode.

9. The display device according to claim 6, wherein the low potential power lines disposed on the plurality of pixel plate patterns are electrically connected to the third connection line.

10. The display device according to claim 6, wherein the low potential power line is further disposed on the planarization layer and the active layer in the plurality of speaker plate patterns,
the low potential power line and the second control electrode are disposed to be spaced apart from each other in the plurality of speaker plate patterns, and
the active layer is spaced apart from the low potential power line with the planarization layer therebetween.

11. The display device according to claim 10, wherein the low potential power lines disposed on the plurality of pixel plate patterns and the low potential power lines disposed on the plurality of speaker plate patterns are electrically connected by the third connection line.

12. The display device according to claim 10, wherein the third connection line includes:
a 3-1-th connection line electrically connecting the speaker power line on the plurality of pixel plate patterns and the first control electrode; and
a 3-2-th connection line disposed to overlap the 3-1-th connection line and electrically connecting the low potential power lines on the plurality of pixel plate patterns and the low potential power lines on the plurality of speaker plate patterns, and
wherein a planarization layer is disposed between the 3-1-th connection line and the 3-2-th connection line.

13. The display device according to claim 2, wherein the lower substrate includes:
a base layer; and
a pattern support layer disposed between the base layer and the plurality of pixel plate patterns and between the base layer and the plurality of speaker plate patterns, and
wherein the pattern support layer includes:
a plurality of pixel support layers overlapping with the plurality of pixel plate patterns; and
a plurality of speaker supports layers overlapping with the plurality of speaker plate patterns.

14. The display device according to claim 13, wherein the pattern support layer of the lower substrate further includes a plurality of first openings disposed between the plurality of pixel support layers and the plurality of speaker support layers,
the plurality of first openings include grooves formed by patterning the pattern support layers, and
a top surface of the base layer is exposed from the plurality of first openings and the plurality of connection lines and the base layer are disposed to be spaced apart from each other in the plurality of first openings.

15. The display device according to claim 13, further comprising:
an upper substrate disposed on the sound unit and the plurality of pixel plate patterns and including a plurality of second openings,
wherein the plurality of second openings include openings passing through the upper substrate, and at least a part of the plurality of second openings overlaps with the sound unit.
